(19) United States
(12) Patent Application Publication
(10) Pub. No.: US 2024/0272713 A1
(43) Pub. Date: Aug. 15, 2024

(54) WEARABLE SENSOR, METHOD OF SENSING USING A WEARABLE SENSOR AND METHOD FOR FORMING A WEARABLE SENSOR

(71) Applicant: National University of Singapore, Singapore (SG)

(72) Inventors: Ajinkya Sarang BHAT, Singapore (SG); Chen Hua YEOW, Singapore (SG)

(21) Appl. No.: 18/567,048

(22) PCT Filed: Jun. 6, 2022
(86) PCT No.: PCT/SG2022/050386

§ 371 Date: Dec. 5, 2023

(30) Foreign Application Priority Data
Jun. 7, 2021 (SG) 10202106029Y

(51) Int. Cl. G06F 3/01; A63F 13/212; B33Y 80/00; G01L 1/18

(52) U.S. Cl. CPC G06F 3/014; B33Y 80/00; G01L 1/18; A63F 13/212

(57) ABSTRACT

A wearable sensor is described. In an embodiment, the wearable sensor comprises: an electrically conductive contacting member adapted to be in constant electrical contact with a first part of a user of the wearable sensor: an electrically conductive sensing member adapted to detect an input via an electrical contact caused by a second part of the user; and a dielectric sandwiched between the contacting member and the sensing member to provide a sensor capacitance, wherein, in use, the constant electrical contact and the electrical contact caused by the second part of the user forms a capacitive circuit comprising a capacitance of a portion of the user in parallel to the sensor capacitance. A method of sensing using the wearable sensor and a method for forming the wearable sensor are also described.

### TECHNICAL FIELD

The present disclosure relates to a wearable sensor, a method of sensing using a wearable sensor and a method for forming a wearable sensor.

### BACKGROUND

The evolution of wearable technologies has led to the development of novel sensors customized for a wide range of applications. It is a general requirement that a wearable sensor possesses a low form factor, is ergonomic and provides minimal impediment to a user's natural movement. A variety of methods and materials have been explored for meeting these requirements. This includes optical, magnetic, and resistive flex sensing, and manufacturing techniques involving 3D printing and the use of liquid metals such as eutectic gallium-indium (EGaln). However, each of these sensing methods or materials has its own drawbacks.

For example, although EGaln sensors generally show high sensitivity, they are required to be fabricated using specialized fabrication equipment. Hysteresis and non-linear response are also major drawbacks of these sensors, especially when they are microchannel-based and require movement of the EGaln. Another example is printable tactile sensors which use materials such as E-TPU (Conductive Thermoplastic Polyurethane), conductive PLA or carbon nanotubes (CNTs) based materials. Although they can be manufactured using a single-step process (e.g. using 3D printing), most of these sensors are resistive in nature which typically have limited gauge factors. Use of auxetic materials has shown to improve the gauge factor, but only to a limited extent. Another limitation of a 3D printed sensor is that it generally has high stiffness, thereby limiting their utility in wearable sensing applications.

In relation to sensing methods, existing wearable sensors for tactile and pressure sensing predominantly use one of the following: piezoresistive sensing, capacitive sensing and piezoelectric sensing. Out of these, piezoresistive sensors in general tend to include materials that are less compliant. They typically possess a higher gauge factor but are usually non-linear over their sensing range. Piezoresistive sensing is also prone to thermal effects and hysteresis. On the other hand, capacitive sensors in general have a lower gauge factor and a lower stretchability. Although capacitive sensors generally have lower hysteresis compared to piezoresistive sensors, their sensing mechanism rely on a change in dielectric properties as a result of mechanical deformation (e.g. using tension or compression). As time is required to materialize and then to reverse a geometric change or a physical change in these capacitive sensors, their sensing mechanism thereby poses limitation in a sensing bandwidth as well as hysteresis of these sensors. Further, capacitive sensors when miniaturized have small capacitances. This leads to a susceptibility to parasitic capacitances and potentially a low signal to noise ratio. Lastly, piezoelectric sensors rely on generation of a charge on application of a pressure. They generally possess high sensitivity but are prone to thermal effects and drift.

Further, practical applications of wearable sensors as input devices are also limited due to a lack of mass producible fabrication methods which do not require specialized equipment. For a wearable input device, low latency (<10 ms) and low form factor are vital for practical utility. Professional gamers, for example can generate over 10 actions per second. In addition, the sensor should ideally possess high specificity, responding only to the signal that it is designed to respond to and rejecting other stray inputs. Challenges still exist in combining these sensor properties, especially without using complex manufacturing methods and specialized equipment. Manufacturing techniques for most current wearable sensors tend to be complex and difficult to scale. Challenges also exist in achieving capacitive sensors with high sensitivity and high noise resistance, and which are robust against false detections.

It is therefore desirable to provide a wearable sensor, a method of sensing using a wearable sensor and a method for forming a wearable sensor which address the aforementioned problems and/or provide a useful alternative.

Furthermore, other desirable features and characteristics will become apparent from the subsequent detailed description and the appended claims, taken in conjunction with the accompanying drawings and this background of the disclosure.

### SUMMARY

Aspects of the present application relate to a wearable sensor, a method of sensing using a wearable sensor and a method for forming a wearable sensor.

In accordance with a first aspect, there is provided a wearable sensor. The wearable sensor comprising: (i) an electrically conductive contacting member adapted to be in constant electrical contact with a first part of a user of the wearable sensor; (ii) an electrically conductive sensing member adapted to detect an input via an electrical contact caused by a second part of the user; and (iii) a dielectric sandwiched between the contacting member and the sensing member to provide a sensor capacitance, wherein, in use, the constant electrical contact and the electrical contact caused by the second part of the user forms a capacitive circuit comprising a capacitance of a portion of the user in parallel to the sensor capacitance.

Thus, the described embodiment provides a wearable sensor. By having the contacting member and the sensing member in electrical contact with the user, a capacitive circuit comprising a capacitance of a portion of the user in parallel to the sensor capacitance can be formed. As a result, a net change in capacitance which can be detected using the wearable sensor can be increased. This provides a number of advantages. First, the wearable sensor has a low latency as the wearable sensor does not rely on a physical change (e.g. deformation of the dielectric) to generate a change in detected capacitance in a tactile sensing mode, but rather, rely on an electrical contact between the sensing member and the second part of the user to provide this net change in detected capacitance. Second, this enables the wearable sensor to be highly sensitive as compared to conventional sensors. By adding a capacitance of the portion of the user, which has a large capacitance, in parallel with the sensor capacitance, the net change in capacitance is large compared to the baseline sensor capacitance. This enables a gauge factor of over 50 to be observed. Third, because there is no physical change (e.g. deformation of the dielectric) involved in providing the net change in capacitance, there is low hysteresis observed and the response time of the wearable sensor is low (e.g. less than 1 ms). Fourth, the large net change in detected capacitance, which is about 2 orders of magnitude to the noise (e.g. stray capacitances or resistances), provides for a high signal to noise ratio for this wearable sensor. Fifth, the wearable sensor is capable of resolving an extremely low force such as less than 0.03 N as a result of the high sensitivity of the wearable sensor. In addition, the wearable sensor can also be used as a pressure sensor which is capable of detecting low magnitude of forces and having a linear response.

The input comprises a direct physical contact between the sensing member and the second part of the user. This provides sensing of a digital input by the wearable sensor.

Where the sensing member is adapted to be in constant electrical contact with the second part of the user and where the dielectric is compressible or at least one of the contacting member and the sensing member is piezoresistive, the input may comprise a force exerted by the second part of the user on the sensing member. This provides sensing of an analogue input (e.g. as a form of pressure) by the wearable sensor.

The second part of the user may include one or more fingers of the user.

The contacting member and the sensing member may each made of a conductive fabric. The conductive fabric provides flexibility and good contact to a skin of the user. This enhances a performance of the wearable device and provides comfort to the user when the wearable sensor is in use.

The wearable sensor may comprise a first protective layer attached to the contacting member and a second protective layer attached to the sensing member for strengthening edges of the conductive fabric of each of the contacting member and the sensing member to prevent fraying. This prolongs an operation lifetime of the wearable user and minimizes maintenance to the contacting member and the sensing member of the sensor.

The dielectric may comprise one or more of: a 3D printed dielectric, a moldable elastomer, a silicone, a compressible dielectric, an insulating foam and an insulating fabric. The dielectric may be formed in a variety of ways depending on the application of the wearable sensor.

In accordance with a second aspect, there is provided a wearable input device. The wearable input device comprising a plurality of input pads, wherein each of the plurality of input pads comprises any one of the preceding wearable sensors.

The wearable input device may be configured to receive a device input provided by having two or more sensing members of the plurality of input pads in electrical contact with one another.

The wearable input device may comprise one of: a wearable keyboard and a wearable glove.

In accordance with a third aspect, there is provided a pressure sensing device for gait analysis, wherein the pressure sensing device comprising two or more preceding wearable sensors, wherein the contacting member of each of the two or more wearable sensors is adapted to be in constant electrical contact with a first part of a foot of the user and the sensing member of each of the two or more wearable sensors is adapted to be in constant electrical contact with a second part of the foot.

Where the two or more wearable sensors may include a first wearable sensor located at a heal area of the foot, a second wearable sensor located at a mid-foot area of the foot and a third wearable sensor located at a toe area of the foot.

The contacting member and the sensing member may made of piezoresistive conductive fabric and/or the dielectric may be compressible.

In accordance with a fourth aspect, there is provided a sensing system. The sensing system comprising any one of the preceding wearable sensors and an integrated circuit for detecting a change in capacitance in response to the electrically conductive sensing member detecting the input via the electrical contact caused by the second part of the user.

In accordance with a fifth aspect, there is provided a sensing method using a wearable sensor, the wearable sensor comprising an electrically conductive contacting member, an electrically conductive sensing member and a dielectric sandwiched between the contacting member and the sensing member to provide a sensor capacitance, the method comprising: placing the contacting member in constant electrical contact with a first part of a user; and detecting an input by the sensing member via an electrical contact caused by a second part of the user, wherein the constant electrical contact and the electrical contact caused by the second part of the user form a capacitive circuit comprising a capacitance of a portion of the user in parallel to the sensor capacitance.

Detecting the input may comprise detecting a direct physical contact between the sensing member and the second part of the user.

Where the sensing member is adapted to be in constant electrical contact with the second part of the user and where the dielectric is compressible or at least one of the contacting member and the sensing member is piezoresistive, detecting the input may comprise detecting a force exerted by the second part of the user on the sensing member of the wearable sensor.

The second part of the user may include one or more fingers of the user.

In accordance with a sixth aspect, there is provided a method for forming a wearable sensor, the method comprising: (i) forming an electrically conductive contacting member of the wearable sensor, the contacting member being adapted to be in constant electrical contact with a first part of a user of the wearable sensor; (ii) forming an electrically conductive sensing member of the wearable sensor, the sensing member being adapted to receive an input via an electrical contact caused by a second part of the user; and (iii) forming a dielectric between the contacting member and the sensing member, wherein the contacting member and the sensing member are made of conductive fabric.

Each of the steps (i) and (ii) may comprise: attaching a protective layer on a surface of the conductive fabric to form a conductive fabric assembly to prevent fraying of edges of the conductive fabric; and shaping the conductive fabric assembly. This prolongs an operation lifetime of the wearable sensor and minimizes maintenance to the contacting member and the sensing member. The conductive fabric assembly may also be shaped according to an application of the wearable sensor.

Where the step (iii) may comprise forming the dielectric using additive manufacturing, the method may comprise: obtaining an electronic file representing a geometry of the dielectric; and controlling an additive manufacturing apparatus to manufacture, over one or more additive manufacturing steps, the dielectric according to the geometry specified in the electronic file.

Where the dielectric may include a moldable elastomer, the step (iii) may comprise: forming a mold; providing the moldable elastomer in the mold; and curing the moldable elastomer.

Embodiments therefore provide a wearable sensor, a method of sensing using a wearable sensor and a method for forming a wearable sensor. By having the contacting member and the sensing member in contact with the user, a capacitive circuit comprising a capacitance of a portion of the user in parallel to the sensor capacitance can be formed. As a result, a net change in capacitance which can be detected using the wearable sensor can be increased. This provides a number of advantages. First, the wearable sensor has a low latency as the wearable sensor does not rely on a physical change (e.g. deformation of the dielectric) to generate a change in detected capacitance in a tactile sensing mode, but rather, rely on an electrical contact between the sensing member and the second part of the user to provide this net change in detected capacitance. Second, this enables the wearable sensor to be highly sensitive as compared to conventional sensors. By adding a capacitance of the user, which has a large capacitance, in parallel with the sensor capacitance, the net change in capacitance is large compared to the baseline sensor capacitance. This enables a gauge factor of over 50 to be observed. Third, because there is no physical change (e.g. deformation of the dielectric) involved in providing the net change in capacitance, there is low hysteresis observed and the response time of the wearable sensor is low (e.g. less than 1 ms). Fourth, the large net change in detected capacitance, which is about 2 orders of magnitude to the noise (e.g. stray capacitances or resistances), provides for a high signal to noise ratio for this wearable sensor. Fifth, the wearable sensor is capable of resolving an extremely low force such as less than 0.03 N as a result of the high sensitivity of the wearable sensor. In addition, the wearable sensor can also be used as a pressure sensor which is capable of detecting low magnitude of forces and having a linear response. Further, in an embodiment, the method of forming the wearable sensor provides for the use of conductive fabric in forming the contacting member and the sensing member of the wearable sensor. The use of conductive fabric provides comfort to the user, while enabling the contacting member to be adapted to be in constant contact with a first part of the user and the sensing member to be adapted to detect an input via an electrical contact with the second part of the user.

### BRIEF DESCRIPTION OF THE DRAWINGS

Embodiments will now be described, by way of example only, with reference to the following drawings, in which:

FIG. 1 shows a schematic of a wearable sensor in accordance with an embodiment;

FIGS. 2A and 2B show illustrations to demonstrate a sensing method using the wearable sensor of FIG. 1 in accordance with an embodiment, where FIG. 2A shows a capacitive circuit of the sensor capacitance in relation to the capacitance of a portion of a user when the sensing member is not in electrical contact with a second part of the user and FIG. 2B shows a capacitive circuit formed comprising the capacitance of a portion of a user in parallel with the sensor capacitance when the sensing member is in electrical contact with the second part of the user;

FIG. 3 shows a flow chart of a sensing method using the wearable sensor of FIG. 1 in accordance with an embodiment;

FIGS. 4A, 4B and 4C show schematic diagrams of a method for forming the wearable sensor of FIG. 1 in accordance with an embodiment, where FIG. 4A shows a diagram illustrating a preparation of materials for forming the different layers of the wearable sensor, FIG. 4B shows a diagram illustrating a trimming of excess materials for shaping the wearable sensor and FIG. 4C shows a diagram illustrating forming electrical contacts to the wearable sensor;

FIGS. 5A and 5B show illustrations for forming an electrically conductive contacting member or an electrically conductive sensing member of the wearable sensor of FIG. 1 in accordance with an embodiment, where FIG. 5A shows an illustration of the materials used to form the contacting member or the sensing member using a Silhouette Cameo®; and FIG. 5B shows an illustration of sewing conductive threads onto the contacting member or sensing member for forming electrical contacts;

FIGS. 6A and 6B show schematic diagrams for forming a dielectric of the wearable sensor of FIG. 1 using additive manufacturing in accordance with an embodiment, where FIG. 6A shows a schematic diagram to illustrate formation of the dielectric and

FIG. 6B shows a schematic diagram to illustrate attaching of the additive manufactured dielectric between a contacting member and a sensing member of the wearable sensor;

FIGS. 7A and 7B show schematic diagrams for forming a dielectric of the wearable sensor of FIG. 1 using a moldable elastomer in accordance with an embodiment, where FIG. 7A shows a schematic diagram to illustrate formation of the dielectric using a 3D printed negative and FIG. 7B shows a schematic diagram to illustrate attaching of the moldable elastomer dielectric between a contacting member and a sensing member of the wearable sensor;

FIGS. 8A and 8B show schematic diagrams for forming a dielectric of the wearable sensor of FIG. 1 using a compressible dielectric (e.g. a foam) in accordance with an embodiment, where FIG. 8A shows a schematic diagram of the compressible dielectric being cut to size and FIG. 8B shows a schematic diagram to illustrate attaching of the compressible dielectric between a contacting member and a sensing member of the wearable sensor;

FIGS. 9A and 9B show different plots of detected capacitance of a wearable sensor and detected force of a load cell versus time to illustrate a minimal force detectable by the wearable sensor in accordance with embodiments;

FIGS. 10A and 10B show plots of detected capacitance of a wearable sensor and detected force of a load cell versus time to illustrate a high frequency input response of the wearable sensor in accordance with an embodiment, where FIG. 10A shows a plot of the detected capacitance and the detected force over a period of 9 seconds and FIG. 10B shows a zoomed-in snapshot of a 1 second sample of the plot of FIG. 10A;

FIGS. 11A and 11B show plots for illustrating a response of a wearable sensor in accordance with an embodiment, where FIG. 11 shows a plot of detected capacitance of the wearable sensor and detected force of a load cell versus time and FIG. 11B shows an activation plot of the wearable sensor and the load cell in relation to the plot shown at FIG. 11A;

FIGS. 12A, 12B and 12C show plots for illustrating a latency of a wearable sensor when used as a tactile sensor in accordance with an embodiment, where FIG. 12A shows a plot of normalised values of the wearable sensor and a load cell collected with a 2 Hz input, FIG. 12B shows a plot of latency between the wearable sensor and the load cell for 20 sample points and FIG. 12C shows a plot of latency as a function of an applied force;

FIG. 13 shows a plot of capacitance measured using a wearable sensor as a function of force applied to the wearable sensor as measured by a compression load cell, up to a force of about 3.1 N, in accordance with an embodiment;

FIG. 14 shows a plot of capacitance measured by the wearable sensor as used in relation to FIG. 13 as a function of force applied to the wearable sensor as measured by the compression load cell, up to a force of about 4.8 N, in accordance with an embodiment

FIG. 15 shows a graph of a loading curve and an unloading curve measured by the wearable sensor as used in relation to FIG. 13, in accordance with an embodiment;

FIG. 16 shows an illustration of a gaming input device comprising a plurality of wearable sensors of FIG. 1 in accordance with an embodiment;

FIGS. 17A and 17B show illustrations of an application of the wearable sensor of FIG. 1 as an insole-based gait analysis sensor in accordance with an embodiment, where FIG. 17A shows an illustration of placements of three wearable sensors in the insole and FIG. 17B shows an illustration of different phases of a gait cycle;

FIGS. 18A and 18B show illustrations of the wearable sensor of FIG. 1 being applied in a wearable control glove for a hemiparetic patient in accordance with an embodiment, where FIG. 18A shows an illustration of the wearable control glove to be worn on a healthy hand of the hemiparetic patient and FIG. 18B shows an illustration of controls provided on the assisted hand in relation to a combination of inputs provided by the wearable control glove;

FIGS. 19A and 19B show illustrations of the wearable sensor of FIG. 1 being applied in an input device to a computer or laptop in accordance with an embodiment, where

FIG. 19A shows an illustration of the input device as a gaming input and FIG. 19B shows an illustration of the input device as a keyboard;

FIG. 20 shows a diagram of an extended circuit formed comprising the capacitance of a portion of a user in parallel with the sensor capacitance when the sensing member is in electrical contact with the second part of the user, including a microcontroller for detecting a change of capacitance and relevant resistances, in accordance with an embodiment;

FIG. 21 shows a plot of capacitance measured using a wearable sensor to illustrate examples of rejected peaks which are removed for high frequency analysis of the wearable sensor in accordance with an embodiment;

FIG. 22 shows plots of normalised values of a wearable sensor and normalised values of a load cell for illustrating missed peaks of the load cell in accordance with an embodiment;

FIG. 23 shows plots of normalised values of a wearable sensor to illustrate activation peaks detection of the wearable sensor by applying a normalised sensor threshold value of 0.2 in accordance with an embodiment; and

FIG. 24 shows plots of normalised values of a load cell to illustrate activation peaks detection of the load cell by applying a normalise load cell threshold value of 0.2 in accordance with an embodiment.

### DETAILED DESCRIPTION

Exemplary embodiments relating to a wearable sensor, a method of sensing using a wearable sensor and a method for forming a wearable sensor are described.

The present disclosure describes a wearable sensor capable of high bandwidth sensing with a superior signal to noise ratio, sensitivity, and capacity to detect ultra-low forces. The wearable sensor distinguishes itself from current capacitive sensor by coupling itself with a user, allowing for greater noise rejection and exceptionally high gauge factor. Commonly, capacitive sensors rely on a change in dielectric properties, usually by mechanical deformation due to tension or compression. This leads to a limitation in the bandwidth of sensing as well as hysteresis as the geometric or physical change requires time to materialize and then to reverse.

Conventional capacitive sensors usually work on the basis of geometric effects. The capacitance, C, of such a capacitive sensor is given by

$$C = ϵ \frac{A}{d}$$

where A is the cross-sectional area of the sensor, d is the plate separation and e is the permittivity of the dielectric.

On compression, d reduces and due to Poisson's ratio, A increases leading to an increase in a capacitance of the sensor. Geometric effects such as these, however, are slow due to their physical nature, and often leads to hysteresis due to their mechanical nature. Reliance on geometric effects by these capacitive sensors also limits their gauge factor and their sensing range. In addition, deformation over time and use can lead to a permanent drift in certain sensors. Further, in most capacitive sensors, stray capacitances can often pose issues, throwing off the sensor calibration and leading to false detections. This has been observed in certain cases on capacitive touch screens, where grease and dirt can often cause false touch detections. It is important to either avoid this interference or develop a safeguard against it for consistent detection.

The wearable capacitive sensor of the present disclosure circumvents this by having one of its plates (i.e. a contacting member of the sensor) being connected to a user, while having the other of its plates used as a sensing member so that a capacitance of the user will be provided in parallel to a capacitance of the wearable sensor when the user makes electrical contact (e.g. direct physical contact) with the sensing member, leading to a spike in the net capacitance measured. This sensing mechanism (or “human-in-loop” (HIL) sensing mechanism), as will be explained in relation to FIGS. 2A and 2B, allows for a high signal to noise ratio, as the order of magnitude of the measured capacitance is about 3 orders higher than that of noise/stray capacitances and two magnitudes higher than a baseline capacitance of the sensor.

The wearable sensor of the present disclosure can be formed using off-the-shelf electronic textiles (also “e-textiles”). E-Textiles are popular for wearable sensing due to their ability to conform to the human body. They are typically used as standalone piezoresistive materials or as capacitive sensors with a variety of dielectrics. Further, as will be explained below, manufacturing a wearable sensor using such e-textiles does not require any specialized equipment or materials. A method of forming the wearable sensor in accordance with an embodiment is described in relation to FIGS. 4A to 8B.

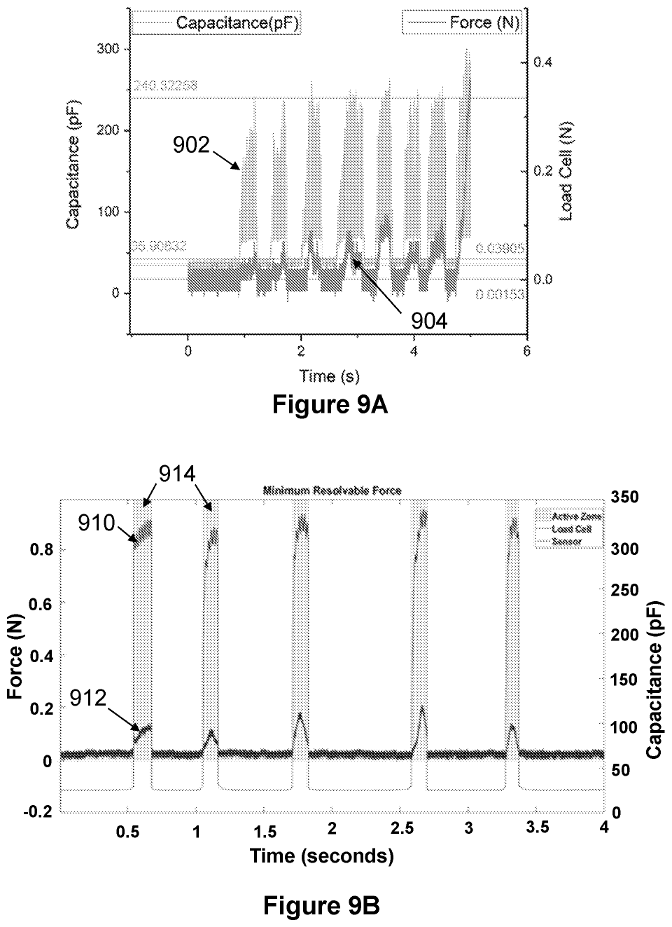

As will be discussed in relation to FIGS. 9A to 15 below, the wearable sensor of the present disclosure can be used in two modes—(i) a tactile sensing mode for touch sensing and (ii) a pressure sensing mode for distinguishing contact pressures.

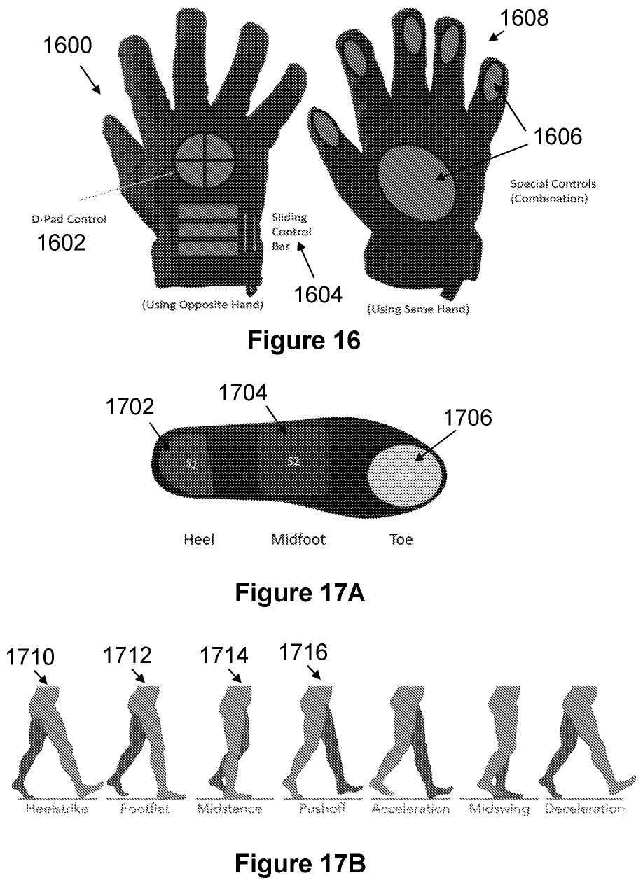

In addition, the sensor of the present disclosure using the human-in-loop (HIL) sensing mechanism provides high sensitivity, high sensing bandwidth as well as ultralow latency which makes it ideal as a wearable input device. An added unique advantage of HIL sensing is that of specificity to the wearer. This means that only the wearer can trigger the sensor at any given time, which is important for wearable applications. This is enabled by a high signal to noise ratio, that allows us to ignore small capacitance changes due to stray capacitances and environmental effects. Applications of the wearable sensor are discussed in relation to FIGS. 16 to 19B.

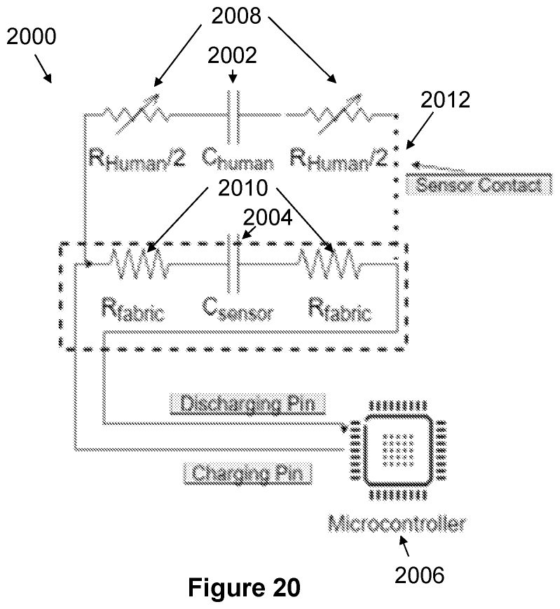

Further materials for explaining the HIL circuit as well as some of the experimental results are discussed in relation to FIGS. 20 to 24.

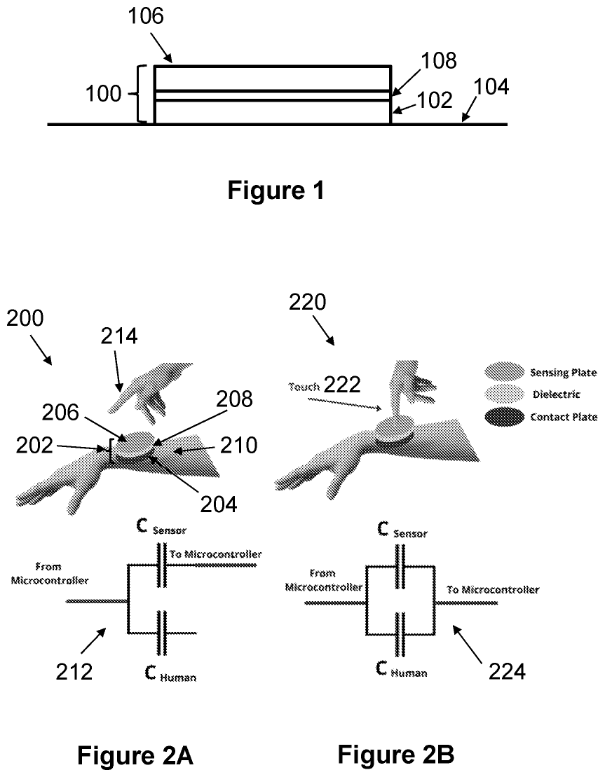

FIG. 1 shows a schematic of a wearable sensor 100 in accordance with an embodiment. As shown in FIG. 1, the wearable sensor 100 comprises an electrically conductive contacting member 102 adapted to be in constant electrical contact with a first part 104 of a user of the wearable sensor 100. As will be described in subsequent Figures, the first part 104 of the user may be an arm or a foot or any body part of the user. The wearable sensor 100 also includes an electrically conductive sensing member 106 adapted to detect an input via an electrical contact caused by a second part of the user, and a dielectric 108 sandwiched between the contacting member 102 and the sensing member 106 to provide a sensor capacitance. As will be discussed in more detail in relation to FIGS. 2A and 2B, when the wearable sensor 100 is in use, the constant electrical contact between the contacting member 102 and the electrical contact detected by the sensing member 106 as caused by the second part of the user forms a capacitive circuit comprising a capacitance of a portion of the user in parallel to the sensor capacitance. This greatly increases a net capacitance measured as compared to a standalone capacitive sensor, thereby providing the advantages of the present wearable sensor 100. An example of the wearable sensor 100 and its exemplary manufacturing process are described in relation to FIGS. 4A to 8B.

FIGS. 2A and 2B show illustrations to demonstrate a sensing method or mechanism for using the wearable sensor 100 of FIG. 1 in accordance with an embodiment. The illustrations show a tactile sensing method utilising the wearable sensor 100 with the HIL mechanism.

On an upper panel 200 of FIG. 2A, it is shown an exemplary wearable sensor 202 in a form of a patch comprising a contacting member or contact plate 204, a sensing member or sensing plate 206, and a dielectric 208 sandwiched between the contacting member 204 and the sensing member 206. The contacting member 204 and the sensing member 206 can be made of conductive fabrics. As shown in the upper panel 200, the contacting member 204 is in electrical contact with a first part 210 of a human user. In this case, the first part 210 of the human user is a foreman of the user. A lower panel 212 of FIG. 2A shows an equivalent capacitive circuit formed comprising a capacitance of the wearable sensor 202 in parallel with a capacitance of a human user or a portion of the human user. As shown in the lower panel 212, when the sensing member 206 is not in electrical contact or physical contact with a second part 214 of the user (e.g. a finger or hand of the user), the capacitive circuit is open and the capacitance of the human user is not part of the capacitive circuit. In this case, the capacitance measured by the microcontroller is the capacitance of the sensor, with the addition of some noise due to contact effects.

FIG. 2B shows illustrations of the capacitive circuit when the sensing member 206 is in electrical contact with the second part of the user. As shown in an upper panel 220 of FIG. 2B, the second part 214 of the user provides a touch 222 to the sensing member 206 of the wearable sensor 202. This leads to a completion of a parallel capacitance loop which effectively adds the human as a parallel capacitance in the equivalent circuit. This leads to a net increase in the resistance and/or capacitance detected by the microcontroller. This is shown in a lower panel 224 of FIG. 2B. In other words, the human user touching the tactile sensor acts as completion of the parallel capacitive circuit. In an exemplary sensing method using this HIL mechanism, the wearable sensor 202 can be charged and discharged using the microcontroller and the capacitance can be measured and/or calculated using a timing constant measured by the microcontroller. The moment the user touches the sensing member 206 of the wearable sensor 202, the net capacitance of the circuit increases which can then be detected by a timing circuit.

This sensing method which is based on the user of a human in loop (HIL) mechanism avoids common issue faced by conventional capacitive sensors, as well as provides a high sensitivity and a high signal-to-noise ratio is proposed. Since this sensing method does not rely on any physical change, the wearable sensor can respond with ultralow latency. The human resistance and the human-fabric contact resistances are responsible for most of the noise in the measurement. This is because the measurement mechanism is in relation to a timing circuit. An RC timing circuit measures the timing constant t (i.e. the time taken to charge to 63.2% is known) which is given by:

$$τ = RC$$

where R is the approximate series resistance and C is the capacitance to be measured. If the resistance in series is approximately known, the timing constant can be used to estimate the capacitance in series. As illustrated in FIG. 2B, however, due to a presence of a human user being introduced into the equivalent capacitive circuit, the effective resistance is no longer constant. This throws off an accurate measurement of the capacitance using the above timing circuit. However, due to a magnitude of the change in capacitance and/or resistance, this does not pose a problem, and the sensor can be calibrated using empirical data in order for it to provide viable sensing. This is especially useful as the human resistance can be very difficult to model accurately and is often variable. The contact resistance (not shown) is even harder to model in this calibration due to its highly dynamic nature, and this can be filtered out empirically. As an example, to filter noise in data caused by e.g. the contact resistances, the mean and variance of the baseline noise for a five-second data sample can be computed and stored in memory. A threshold can then be set and adjusted to a value of mean+k*variance, where k is usually 3-5, to filter out the noise. An extended circuit diagram which includes the relevant resistances will be described in relation to FIG. 20 below.

As discussed above, the HIL sensing mechanism therefore allows several advantages, such as: (i) high sensitivity, as the human capacitance introduced parallel to the sensor capacitance means that the sensor response can be large; (ii) high sensor specificity, as the sensor cannot be triggered by anyone other than the user given that there is no other means to complete the HIL capacitive circuit effectively. The effect of a combination of these properties synergistically provides a conservative threshold which allows for robust detection without sacrificing responsiveness of the sensor.

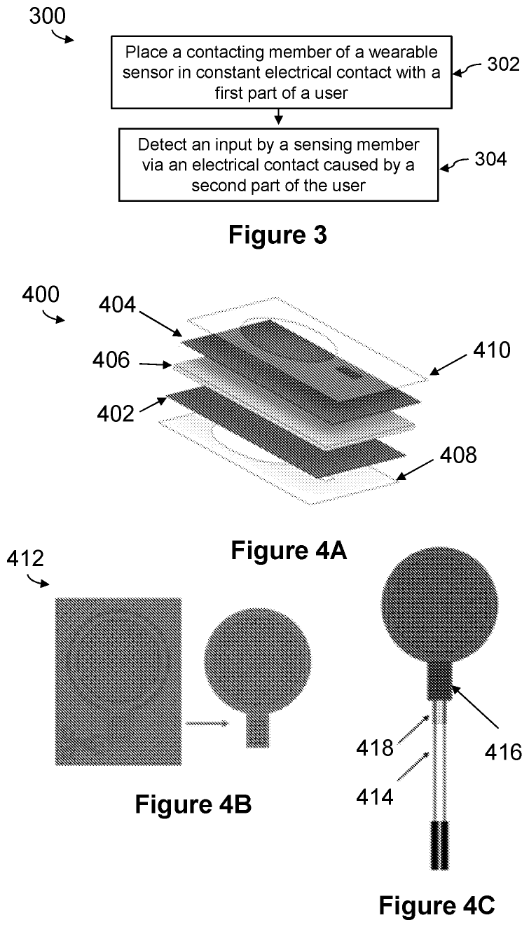

FIG. 3 shows a flow chart of a sensing method 300 using the wearable sensor 100 of FIG. 1 in accordance with an embodiment

In a step 302, the contacting member 102 of the wearable sensor 100 is placed in constant electrical contact with a first part 104 of a user. This provides for a first electrical contact between a human capacitance and the sensor capacitance.

In a step 304, an input is detected by the sensing member 106 of the sensor 100 via an electrical contact caused by a second part of the user. As demonstrated in relation to FIGS. 2A and 2B, the constant electrical contact and the electrical contact caused by the second part 214 of the user form a capacitive circuit comprising a capacitance of a portion of the user in parallel to the sensor capacitance. This closes the equivalent capacitive circuit as discussed and provides the aforementioned advantages.

FIGS. 4A, 4B and 4C show schematic diagrams of a method for forming the wearable sensor 100 of FIG. 1 in accordance with an embodiment. For a soft sensor to be mass manufacturable and repeatable in production, the fabrication methods need to be standardized and automated if possible. To ensure repeatable fabrication, the Silhouette Cameo® (Silhouette Inc., USA) was used in the present embodiment, as a plot cutter, for cutting the conductive fabric into the appropriate shapes for forming the wearable sensor. The fabrication technique involves preparation of the materials, trimming, and attaching connectors, as discussed below in relation to FIGS. 4A, 4B and 4C.

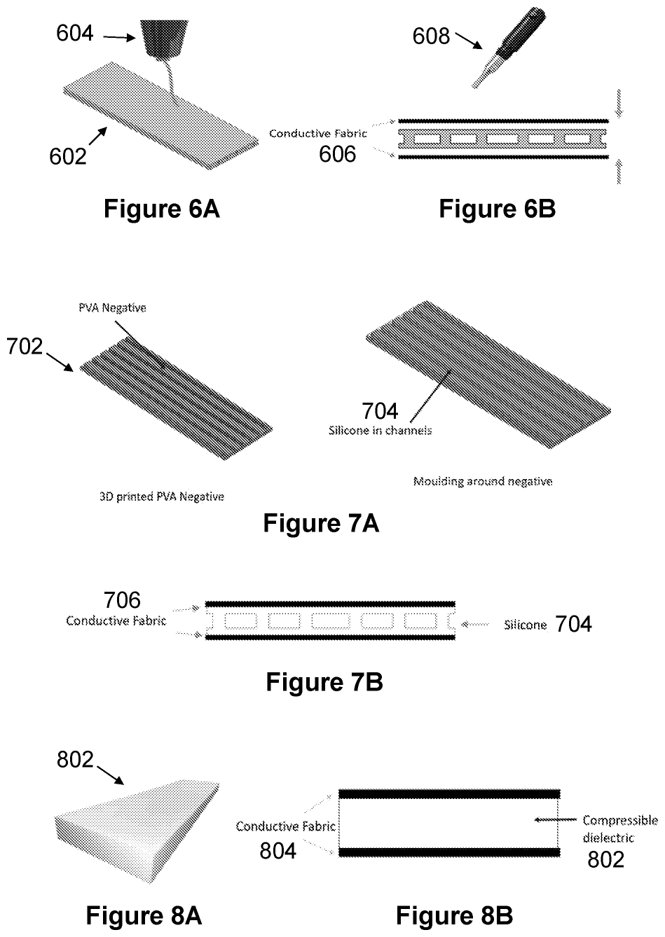

FIG. 4A shows a diagram 400 illustrating the preparation of materials for forming the different layers of the wearable sensor in accordance with an exemplary embodiment. As shown in FIG. 4A, the wearable sensor comprises a contacting member 402, a sensing member 404 and a dielectric 406 sandwiched between the contacting member 402 and the sensing member 404. It should be appreciated that the wearable sensor can be symmetrical (e.g. as shown in FIG. 4A), which means that the contacting member 402 and the sensing member 404 can function interchangeably (i.e. the sensing member can be in constant contact with a first part of the user and the contacting member can detect an input via an electrical contact with a second part of the user, and vice versa). In other embodiments, the contacting member and the sensing member of a wearable sensor can be asymmetrical. In the present embodiment, the contacting member 402 and the sensing member 404 are made of conductive fabric. The conductive fabric used can be any conductive fabric such as EeonTex from Eeonyx™ or Knit Jersey Conductive Fabric from Adafruit™. These fabrics were chosen due to their high conductivity as well as availability. It was found that the EeonTex fabric was easier to cut precisely whereas the Adafruit™ fabric tends to fray. The EeonTex fabric, however, was observed to have a higher resistance (about 100Ω for a 6 mm×2 mm piece of EeonTex fabric) as compared to a resistance of about 5Ω for an Adafruit™ fabric of the same size. The Adafruit™ fabric was chosen for use in the wearable sensor in this case, for its low resistance and high stretchability, as well as high sensitivity when compressed. The dielectric 406 used can vary depending on the applications of the wearable sensor. In the present embodiment, neoprene was used as the dielectric 406. Examples of other suitable dielectrics are discussed in relation to FIGS. 6A to 8B. FIG. 4A also shows a first protective layer 408 to be attached to the contacting member 402 and a second protective layer 410 to be attached to the sensing member 404. Given the tendency for the Adafruit™ to fray, these protective layers 408, 410 aid to strengthen the edges of the conductive fabric of each of the contacting member 402 and the sensing member 408 to prevent fraying of the Adafruit™ conductive fabric. A suitable material for use as the protective layers 408, 410 includes magic tape or painter's tape. Depending on the applications of the wearable sensor, it should be appreciated that the materials used for the conducting member 402 and the sensing member 404 can be different from each other as long as they are both electrically conducting, or that the materials used for the first protective layer 408 and the second protective layer 410 can be different as long as each of them function to prevent fraying. It should also be appreciated that the first protective layer 408 and/or the second protective layer 410 are optional depending on the materials used for the contacting member 402 and the sensing member 404.

FIG. 4B shows a diagram 412 illustrating a trimming of excess materials for shaping the wearable sensor in accordance with an embodiment. Once the contacting member 402 and the sensing member 404 are cut to size using the plot cutter Silhouette Cameo®, an appropriate dielectric 406 can be attached in between the contacting member 402 and the sensing member 404. The first protective layer 408 and the second protective layer 410 can then be attached or adhered to the contacting member 402 and the sensing member 404, respectively as shown in FIG. 4B. In the present embodiment where magic tape was used as the protective layers, appropriate windows (e.g. as shown in FIG. 4A) can also be formed so that the protective layers each acts like a stencil exposing an area of the conductive fabric members/plates for contacting the user, while preventing fraying of the conductive fabric. The excess protective layers can then be trimmed off by hand or a plot cutter, as shown in FIG. 4B.

FIG. 4C shows a diagram illustrating the forming of electrical contacts of the wearable sensor 100. The electrical contacts 414 (e.g. leads or wires) are connected to an exposed area or portion 416 of the wearable sensor. In the present embodiment, the electrical contacts 414 were connected by soldering, and were secured using an insulating heat shrink or electrical tape 418 as shown in FIG. 4C. It should be appreciated that the electrical contacts 414 can be formed by other means (e.g. using conductive tapes etc.).

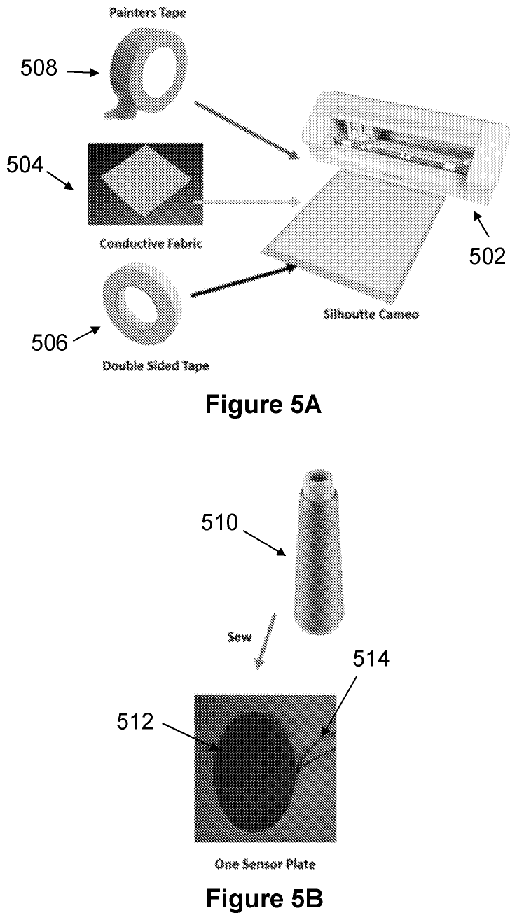

FIGS. 5A and 5B show illustrations of forming the contacting member 402 or the sensing member 404 of the wearable sensor of FIG. 4C in accordance with an embodiment.

FIG. 5A shows an illustration of the materials used to form the contacting member or the sensing member using a Silhouette Cameo® 502 in accordance with the present embodiment. It should be appreciated that other cutting method for forming the contacting member and/or the sensing member can be used.

To be able to cut a conductive fabric 504 (e.g. Adafruit™ conductive fabric) to size without fraying, a multistep process was employed using the Silhouette Cameo® 502. First, double sided tape 506 was used to tape the conductive fabric 504 on a silhouette cutting mat for better adhesion. Next, the conductive fabric 504 on the silhouette cutting mat was layered with painter's tape 508 to secure it on the silhouette cutting mat to prevent movement of the conductive fabric 504 during cutting. The painter's tape 508 adds stiffness and prevents fraying, while helping to keep the conductive fabric 504 in place and aids the blade of the Silhouette Cameo® 502 in cutting through. A suitable design for the conducting member and/or the sensing member can then be sent to the Silhouette Cameo's software to cut the conductive fabric to a desired shape and size to form an electrically conductive plate (e.g. the contacting member or the sensing member). This exemplary method using the Silhouette Cameo® 502 allows for repeatable cutting with minimal fraying. The painter's tape 508 may be left on the conductive plate or removed post cutting with negligible impact on the sensor performance. Using this method, the contacting member and/or the sensing member can be cut into any shape as per a desired requirement, thus giving the sensor versatility to be used in varied applications.

FIG. 5B shows an illustration of sewing conductive threads 510 onto the contacting member or sensing member for forming electrical contacts. Once the electrically conductive plates 512 are formed as illustrated in FIG. 5A, the electrically conductive plates 512 formed by the conductive fabric 504 can be sewn with conductive thread which provides electrical contacts 514 to these plates. It should be appreciated that other methods for forming the electrical contacts 514 can be used (e.g. see FIG. 4C).

As illustrated by FIGS. 5A and 5B, this exemplary fabrication process using the Silhouette Cameo® 502 is therefore simple and repeatable. Exemplary embodiments of the wearable sensor as presented in the disclosure were fabricated using conductive fabrics and conductive threads, making them suitable for use as soft sensors or wearable sensors.

FIGS. 6A to 8B illustrate a number of suitable dielectrics which can be used in the wearable sensor of the present embodiments, as well as their manufacturing methods.

FIGS. 6A and 6B show schematic diagrams for forming a dielectric 602 of a wearable sensor using additive manufacturing in accordance with an embodiment.

FIG. 6A shows a schematic diagram illustrating a formation of the dielectric 602 by additive manufacturing (AM), such as 3D printing or fused deposition manufacturing (FDM). A Computer Aided Design (CAD) software is used to design the required pattern of the dielectric 602. This can then be sent to an appropriate slicer which generates the code (e.g. the G-code) for the AM machine 604. In other words, an appropriate electronic file (e.g. a CAD file) representing a geometry of the dielectric is obtained and used in the AM machine 604 for controlling it to form, over one or more additive steps (depending on the material(s) of the dielectric used) the dielectric 602. Flexible Thermoplastic Polyurethanes (TPU) variants such as Polyflex and X60 may be used as materials for the dielectric 602. Water soluble or water washable supports may be used for complex structures. There is also a possibility of using multimaterial printers such as the Stratasys which can print using soft materials such as Agilent and TangoBlack and water washable supports.

FIG. 6B shows a schematic diagram to illustrate attaching of the dielectric 602 between conductive fabric 606 for forming a wearable sensor. In an embodiment where thermoplastics is used for forming the dielectric 602, heat welding (e.g. by using an ultrasonic welder 608) of the of the conductive fabric plates 606 is recommended as it is a secure method of attaching the additive manufactured dielectric 602. Alternatives for attaching the dielectric 602 to the conductive fabric plates 606 includes using specialized plastic adhesives, which is particularly relevant for non-thermoplastic materials. The exact specialized adhesive to be used may vary based on the material choice of the dielectric.

FIGS. 7A and 7B show schematic diagrams for forming a dielectric of a wearable sensor using a moldable elastomer in accordance with an embodiment.

FIG. 7A shows a schematic diagram illustrating formation of a dielectric using a 3D printed mold 702. The dielectric in this case comprises a moldable elastomer, such as silicone. A sacrificial material (e.g. Polyvinyl alcohol (PVA)) is used as a temporary structural construct, which functions as a negative. The moldable elastomer 704 (such as silicone) can then be provided in the PVA negative, and cured to form a solid dielectric.

FIG. 7B shows a schematic diagram to illustrate attaching of the dielectric 704 between conductive fabric plates 706 for forming a wearable sensor. In the present embodiment, once the moldable elastomer 704 are cured in the negative, this assembly can be attached between the conductive fabric plates 706 using an adhesive or a suitable plastic glue. The negative can then be dissolved to form the dielectric between the conductive fabric plates 706 as shown in FIG. 7B.

FIGS. 8A and 8B show schematic diagrams for forming a dielectric of the wearable sensor of FIG. 1 using a compressible dielectric (e.g. a foam) in accordance with an embodiment.

FIG. 8A shows a schematic diagram of the compressible dielectric 802 being cut to size. The dielectric can be sandwiched between two conductive fabric capacitor plates 804 and adhered using an adhesive. This embodiment is useful to create a compression sensor due to high porosity and compressibility of the compressible dielectric 802 for high compression response.

Another suitable dielectric which may be used in wearable sensors in accordance with embodiments of the present disclosure includes a fabric dielectric. The fabric dielectric may be resistive or insulating. The fabric dielectric can be cut to size (e.g. using the Silhouette Cameo® as previously discussed), and attached between two conductive fabric plates using a fabric adhesive for forming a wearable sensor. In an embodiment, conductive threads can be sown into the two conductive fabric plates to form electrical contacts prior to adhering the fabric dielectric between the conductive fabric plates.

FIGS. 9A to 15 illustrate experiments performed using the wearable sensor of FIG. 4C. The wearable sensor can be used in two modes—(i) a tactile sensing mode for touch sensing and (ii) a pressure sensing mode for distinguishing contact pressures.

The first mode is the tactile sensing mode. The tactile sensing mode can be thought of as an on/off mode that detects the presence or absence of a touch. Thus, it can function as a digital input to a device. The sensor is mounted in such a way that there is a constant electrical contact between one plate (e.g. a conducting member of the sensor) and the user. The other plate acts as a sensing member and when touched, the sensor detects a spike in capacitance that can be read using an electronic platform such as the Arduino®.

For the tactile sensing mode, a Honeywell FSAGPNXX1.5LCAC5 load cell with a 1.5 lbs operating range was used. This provides a sufficient range of calibration for the operating range of the sensor with a high resolution. The setup consists of a bracket for mounting the load cell. The load cell is placed below the sensor such that the pressure applied on top of the sensor is transferred directly onto the load cell. In this setup, the sensor and the load cell were connected to a Teensy 4.0 running a 10-bit ADC at a sampling rate of 20 kHz for synchronizing the data. Before the start of the experiment, the load cell was calibrated using standard weights in the range of 100-600 grams to account for bias and to gauge linearity. For each of these setups, a timing circuit was used for the measurement of the capacitance.

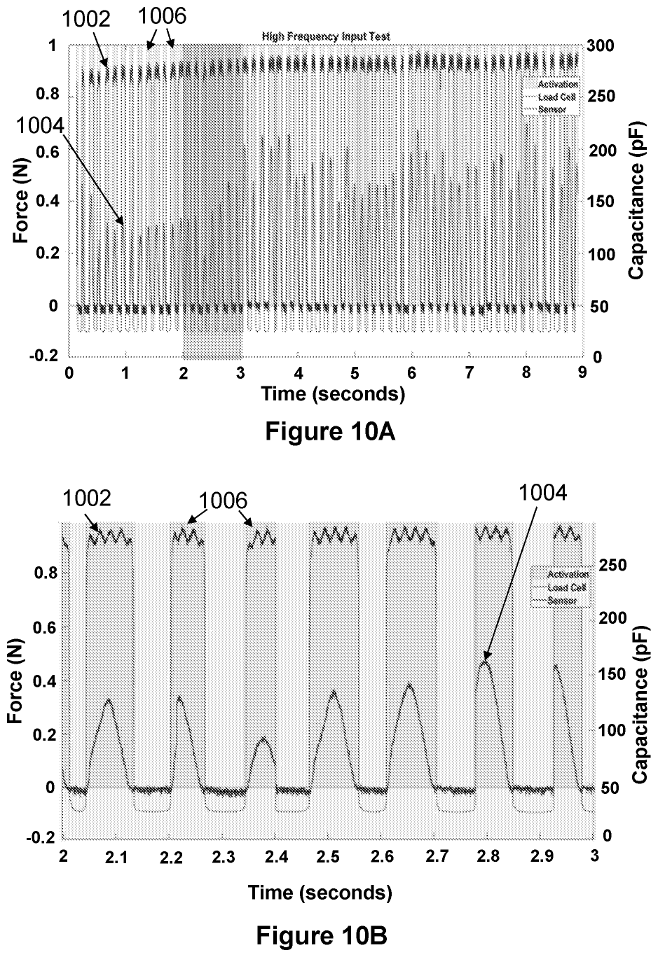

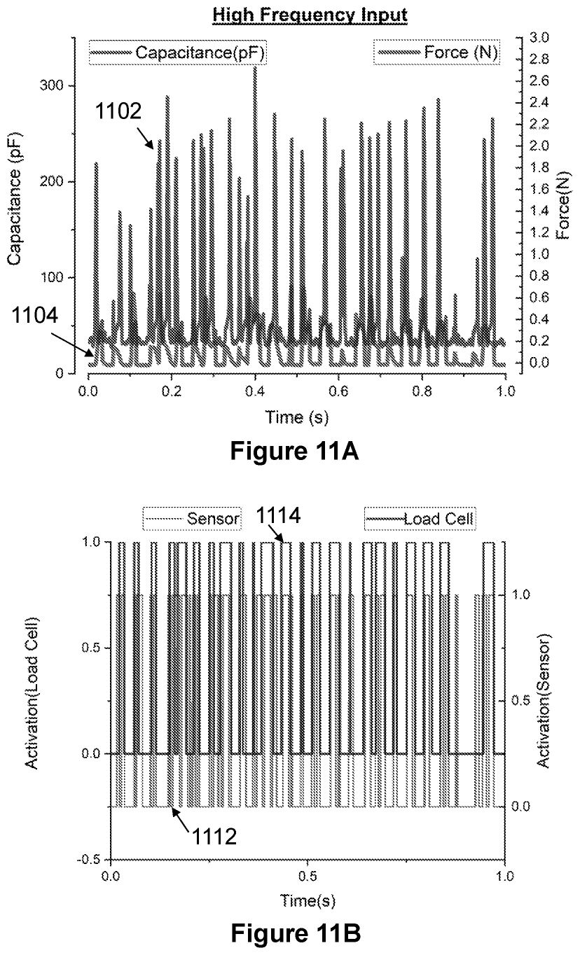

The dynamic response and latency of the sensor were evaluated for this tactile mode. Since the sensor relies on parallel capacitance to be formed, a human subject was recruited. Two sets of experiments were performed to determine the minimum resolvable force and maximum sensing frequency of the sensor. In the first experiment (data as shown in relation to FIGS. 9A and 9B), the subject was instructed to touch the sensor as lightly as possible, and the force of the load cell and the capacitance of the sensor were measured. In the second experiment (data as shown in relation to FIGS. 10A, 10B, 11A and 11C) the subject was instructed to generate as many taps as possible during a five second interval. The load cell was used as the “ground truth” for the experiments, while the sensor capacitance was the measured variable. The objectives of the tests were to determine the accuracy of the sensor detection, and its capacity to sense a high input frequency.

FIGS. 9A and 9B show plots of detected capacitance of a wearable sensor and detected force of a load cell versus time to illustrate a minimal force detectable by the wearable sensor of FIG. 4C. These results relate to the first experiment as afore described when the sensor is used as a tactile sensor.

FIG. 9A shows plots of measured capacitance 902 using the sensor and measured force 904 of the load cell versus time to illustrate the minimum force that can be resolved using the sensor in the tactile mode. As shown from the plot of FIG. 9A, the sensor could resolve very small forces, with magnitudes smaller than 0.03 N or about 3 g, which is close to a minimum resolution of the load cell used. The force of 0.03 N is much smaller than an average force of a human touch which is found to be around 0.6 N or 60 g. It is theoretically possible that the sensor can resolve even smaller forces, although this may not be necessary given that the sensor is unlikely to encounter such a magnitude of force in practical situations. Furthermore, such low magnitudes are likely to be unintentionally applied in a practical setting. As shown in FIG. 9A, the sensor response was substantially large even for a small input force. The signal noise observed in FIG. 9A was likely due to the sliding of the subject's finger on the sensing surface of the sensor while applying such a small force. Similar effects are seen in most wearable sensors and electrodes and often categorized as interface noise. Despite this, a high sensitivity means that a conservative threshold of 70 pF or 80 pF (from a baseline value of about 20 pF) can still be useful for detection.

FIG. 9B shows plots of measured capacitance 910 using the sensor and measured force 912 of the load cell versus time to illustrate the minimum force that can be resolved using the sensor in the tactile mode in accordance with a second embodiment. Active zones 914 of the sensor are also shown in FIG. 9B.

FIGS. 10A and 10B show plots of detected capacitance of a wearable sensor and detected force of a load cell versus time to illustrate a high frequency input response of a wearable sensor. These results relate to the second experiment as afore described when the sensor is used as a tactile sensor. The Y axes for each of the plots in FIGS. 10A and 10B have been offset for ease of viewing.

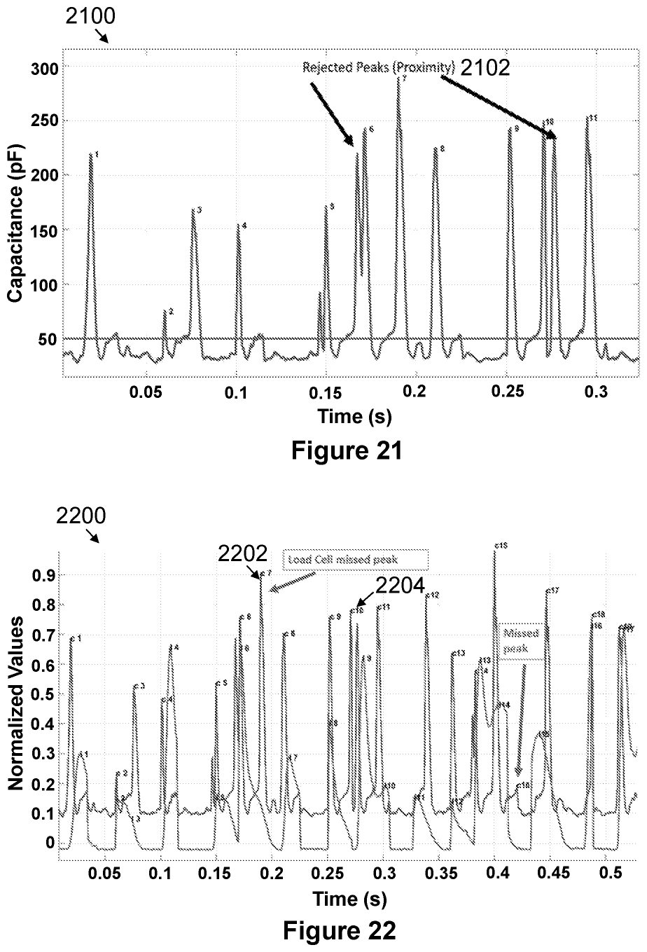

FIG. 10A shows a plot of the detected capacitance 1002 using the sensor and detected force 1004 using the load cell over a period of 9 seconds. A threshold filter was used for obtaining the detected capacitance 1002, and this is discussed in relation to FIGS. 21 and 22 below. The activation zones 1006 are also shown, which indicates the time when the sensor would be in the activated mode based on a threshold of 50 pF. The sensor baseline was 25 pF, which raised to over 250 pF upon electrical contact with the subject as shown in FIG. 10A.

FIG. 10B shows a zoomed-in snapshot of a 1 second sample of the plot of FIG. 10A. Similar references for like features of FIG. 10A were used in FIG. 10B. As shown in FIG. 10B, responses of the tactile sensor and the load cell overlap quite well. This demonstrates that the sensor can detect the same inputs as the high-resolution load cell, demonstrating high accuracy. The activation zones 1006 as shown in FIG. 10B provide visual confirmation to highlight this, and to show responses of the sensor and the load cell should these be used in isolation as a control input with a thresholding-based activation scheme. Also observed in the plots of FIG. 10B is that the sensor exhibited low latency as shown by the almost instant peaking upon contact, while the data of the load cell displayed a distinct lag. This can be attributed to the fact that the sensor relies primarily on an electrical phenomenon (i.e. the HIL mechanism) whereas the load cell relies on electrical effects of a primarily mechanical phenomenon (i.e. strain). Further, the plots as shown in FIG. 10B also shows good overlap between the responses of the sensor and the load cell, indicating that there was almost no false detection by the sensor. The sensor also shows a tendency to return to its baseline quickly on removal of the input.

FIGS. 11A and 11B show plots for illustrating responses of a wearable sensor and a load cell in accordance with an embodiment. These results relate to the second experiment as afore described when the sensor is used as a tactile sensor, and are similar to those shown in FIGS. 10A and 10B.

FIG. 11A shows plots of detected capacitance 1102 of the wearable sensor and detected force 1104 of the load cell versus time, in response to a high frequency input. Results shown were produced from a one second sample extracted from a five-second experimental trial at random as described in the aforementioned second experiment. This time interval is selected to enable demonstration of the response without clutter. As shown in FIG. 11A, the values of the sensor and the load cell as recorded in the one second sample overlap quite well. This shows that the sensor was able to detect the same input as the high-resolution load cell with almost no false detections by the sensor, demonstrating high sensing accuracy of the sensor. Also shown in FIG. 11A is that the sensor was able to detect two extremely light touches around the 0.9 second mark, which the load cell read at less than 0.1 N.

FIG. 11B shows an activation plot of the wearable sensor and the load cell in relation to the plot shown at FIG. 11A. In FIG. 11B, the data for the sensor 1112 and the data for the load cell 1114 were normalised, and the Y axes had been offset for ease of viewing. The plots of FIG. 11B show what activations may look if the load cell or the sensor were used in isolation as a control input by utilising thresholding-based activation. Also observed in the plots of FIG. 11B is that the sensor exhibited low latency in that it could distinguish some temporally close or temporally adjacent inputs where the load cell was only able to detect a single input (examples at approximately 0.2 seconds and 0.7 seconds mark of the plots of FIG. 11B). This can be attributed to the fact that the load cell relies primarily on a physical change (strain) whereas the sensor relies on a purely electrical phenomenon (i.e. the HIL mechanism) for detection.

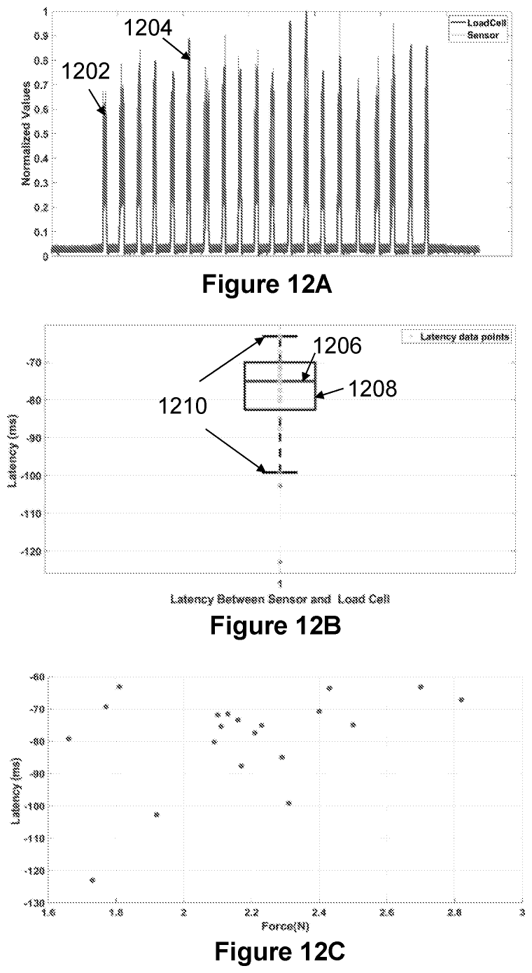

FIGS. 12A, 12B and 12C show plots for illustrating a latency of the wearable sensor of FIG. 4C when used as a tactile sensor in accordance with an embodiment.

FIG. 12A shows plots of normalised values of measured capacitance 1202 of the wearable sensor and measured resistance 1204 of the load cell collected using a 2 Hz input. The 2 Hz tactile input was provided by the user using a metronome. This data set was collected using 2 Hz input to account for the hysteresis seen in the load cell at higher frequencies, which leads to the load cell not returning to its baseline. The sensor latency was measured using the load cell as the reference. The data as shown in FIG. 12A was used to compute the difference in time that it took for the triggering of the sensor threshold with respect to the load cell threshold. More details of this data set and the explanation for using two different data sets will be discussed in relation to FIGS. 21 to 24 below.

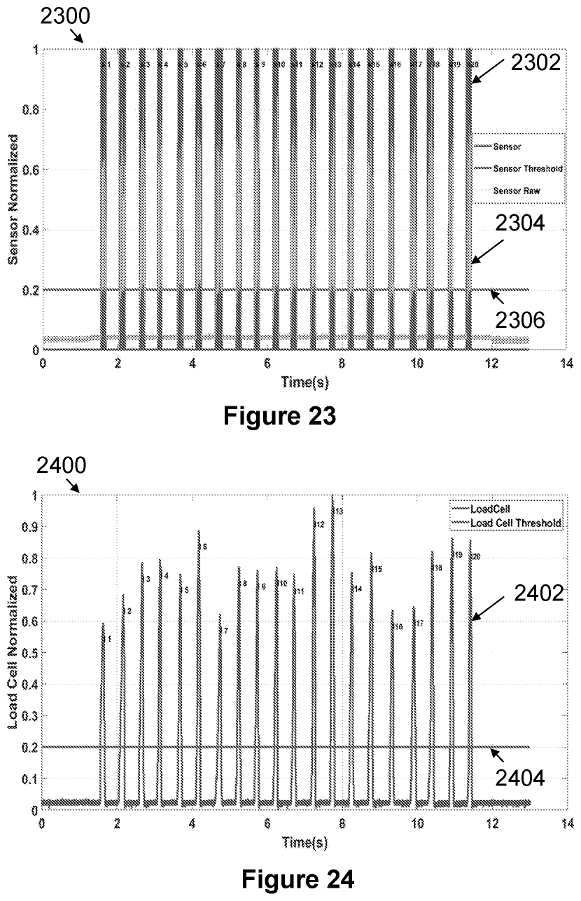

FIG. 12B shows a plot of latency data between the wearable sensor and the load cell using 20 sample points of FIG. 12A. As shown in FIG. 12B, the sensor was on average 78 ms faster than the load cell used for standardization, with a median value 1206 of 75 ms. The box plot 1208 shows the interquartile ranges including the median value 1206. The standard deviation 1210 and the variance were low, at a value of 14.95 ms and 223.06 respectively, indicating that the sensor response was extremely consistent. As can be seen in the point scatter in the box plot 1208, the spread of the points was in an extremely narrow band, with two outliers affecting the variance to a large extent. This consistently low latency is one of the main features of the sensor which enables utility in a variety of wearable applications as an input device. The purpose of the latency test was to show that the latency of the sensor is low enough that it can function well in a wearable application, and the data as shown supported its feasibility. Further detail can be found in relation to FIGS. 23 and 24 below.

FIG. 12C shows a plot of measured latency latency between the load cell and the sensor as a function of measured applied force to the load cell, for investigating if the applied pressure is a nontrivial factor to the load cell latency. A weak correlation was observed which suggests that larger forces tend to trigger the load cell faster, leading to a lower latency difference. However, the data is inconclusive to make a strong claim as the outliers as shown in the scatter plot suggest that the trend is weak.

The signal to noise ratio (SNR) is an important parameter for sensors to allow setting of conservative thresholds for triggering the sensors. This is especially useful when using sensors for digital input. SNR of over 40 dB is usually considered excellent, while SNR in a range of 20 dB to 40 dB is usually considered acceptable.

A notable advantage of the present sensing method is its ability to reject unintended input from environmental sources as well as non-users. Table 1 illustrates the results of the SNR for the wearable sensor 100 of FIG. 1 with respect to environmental and sensing noise (Noiseₑₙᵥ) as well as external user trigger noise referred to as unintended input noise (Noise_{UI}).

The Signal to Noise Ratio (SNR) can be calculated using the following formula:

$$SNR = 20 log \frac{{Signal}_{avg}}{{Noise}_{avg}}$$

where Signal_{avg} is a difference between an average of the intended touch and an average of the baseline.

For computing the rejection of the unintended input, the SNR is computed using:

$$SNR = 20 log \frac{{Signal}_{avg}}{{Noise}_{UI}}$$

where Noise_{UI} is an absolute difference between (a) the average capacitance of the sensor when a non-user touches the sensor and (b) the sensor baseline.

A 5-second average snapshot for each of the variables, namely the baseline, the environmental noise (Noiseₑₙᵥ) and the unintended (external) input (Noise_{UI}) were taken to compute the results as shown in Table 1.

As evidenced by Table 1, the present wearable sensor and its sensing method exhibit a high SNR for the intended user, and allows for easy rejection of environmental noises and non-user-based noises. This feature is of great utility for wearable interfaces that will routinely encounter both sources of noise studied herein.

TABLE 1
Signal to Noise Ratio for the Tactile Sensor

| Measurement | Capacitance Average (pF) | SNR (dB) |
|---|---|---|
| Baseline | 22.7539 | — |
| Intended Touch | 260.0561 | — |
| Environmental Noise (Noiseₑₙᵥ) | 0.0051 | 162.2368 |
| Unintended Input (Noise_{UI}). | 1.2259 | 105.3127 |

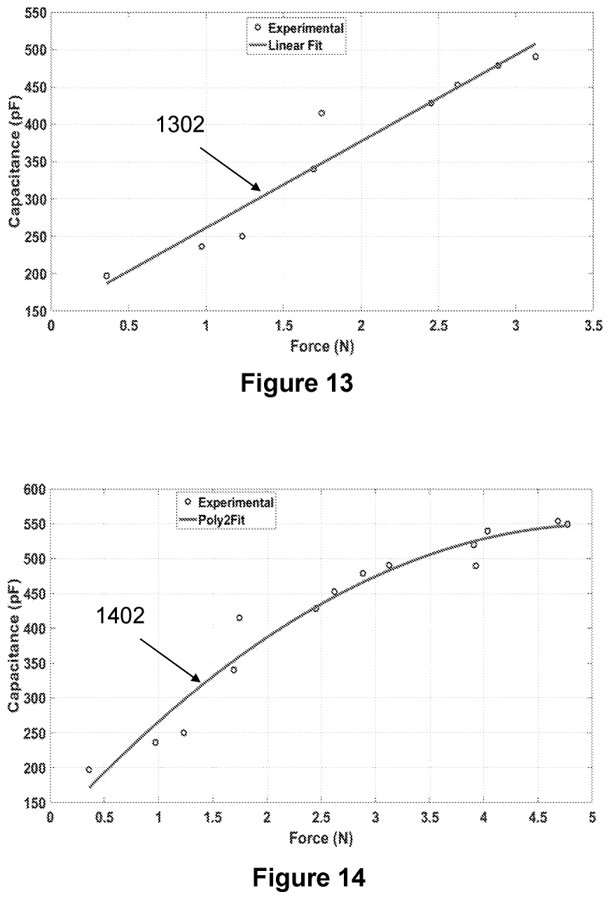

Besides tactile sensing, the wearable sensors of the present embodiments are also capable of pressure sensing, as will be illustrated in relation to FIGS. 13 to 15. This pressure sensing mode adds on to a functionality of the wearable sensor by allowing sensing of the pressure in an analog mode, for example to represent an intensity of a touch. This is distinct to the digital nature of the tactile sensing mode as discussed above. The sensor of the present embodiment can be used as a pressure sensor owing mainly to the piezoresistive properties of the conductive fabric and thread used in forming the contacting member and the sensing member of the sensor. The piezoresistive properties of the conductive fabric enhances the utility of the wearable sensor for use as a pressure sensor. In an embodiment where the contacting member and the sensing member of the wearable sensor are not made of piezoresistive material, the wearable sensor can comprise a compressible dielectric to provide this pressure sensing capability. In this case, the pressure sensing capacity can be attributed to the dielectric being compressed which leads to a reduction in the plate separation, d and thereby an increase in the capacitance measured. This pressure sensing mode enables us to not only isolate user inputs, but also gauge the pressure. As will be demonstrated below, this can be useful in situations where the device is used as a control input.

For the pressure sensing experiments conducted in relation to FIGS. 13 to 15, the sensor was mounted on a wearable glove and the load cell was placed inside the glove and directly underneath the sensor whose capacitance was being measured. The glove was then worn by a human user, and inputs provided by the user were simultaneously measured using the load cell and the wearable sensor in real time. For the experiment, the user was instructed to increase the load on the sensor gradually as the data was recorded, from touching the sensor as lightly as possible to increasing the pressure to the level at which it becomes just uncomfortable. This ensures that the regular range in which the sensor will have to operate was captured, i.e. from a lightest touch to a strongest touch by a user. The data is collected, filtered and random samples are selected from the data as representative samples. For FIGS. 13 and 14, the data collected were also fitted using the MATLAB curve fitting toolbox (this will be discussed in more detail in relation to FIGS. 21 to 24 below). The measured data was sampled using Teensy 4.0 running a 10-bit ADC at a sampling rate of 20 kHz. The data was used to infer a relationship between the pressure applied and the capacitance output of the sensor.

Factors such as a material of the wearable glove used, as well as capacitances induced by the environment and the capacitance of the user, will affect the baseline reading of the sensor, the sensor was therefore tested in this application configuration rather than in isolation. This test configuration also provides a more realistic representation of the performance of the sensor in its recommended working environment, i.e. on a wearable device.

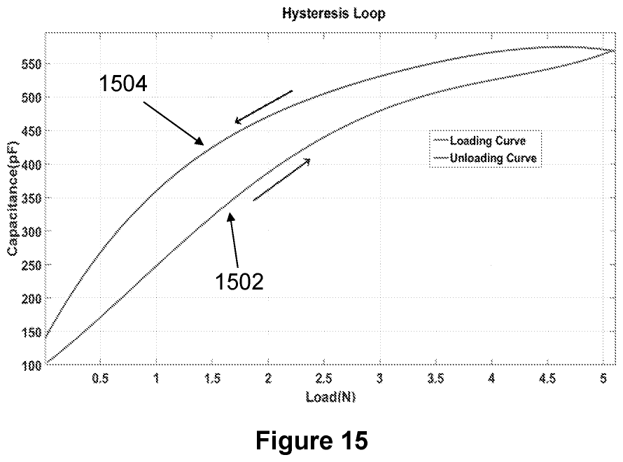

For the pressure sensing experiments, the force to capacitance values recorded as shown in FIGS. 13 and 14 were for a 2.5 cm×2.5 cm sensor pad. The differences between the loading and unloading, and the hysteresis were also recorded as shown in relation to FIG. 15. Models to the empirical data for these pressure sensing experiments could be fitted for use in estimating an applied force, which can be useful for applications such as gait analysis as will be discussed in relation to FIGS. 17A and 17B.

FIG. 13 shows a plot of capacitance measured using the wearable sensor of FIG. 1 as a function of force applied to the wearable sensor as measured by a compression load cell for an applied force of up to about 3.1 N in accordance with an embodiment.

The data as shown in FIG. 13 was fitted to a linear model 1302 using the MATLAB curve fitting toolbox. The linear model 1302 was fitted for a force of up to 3 N or 300 g, which is a likely maximum working range of the sensor for an input device. It is noted that a common tactile input for most devices has a working range of about 0.6 N to 1 N. As shown in FIG. 13, the pressure response of the sensor over this range is quite linear, with a value of R² error being 0.9323 and a RMSE value of 31.3229. This means that in practice, one can simplify the sensor model to a linear model for real-time processing. Thus, the linear approximation model can serve as a good gauge of the applied force in this range and can be used for calibration.

FIG. 14 shows a plot of capacitance measured using the wearable sensor of FIG. 1 as a function of force applied to the wearable sensor as measured by a compression load cell for an applied force of up to about 4.8 N in accordance with an embodiment. The data as shown in FIG. 14 was fitted to a polynomial (degree=2) model 1402 using the MATLAB curve fitting toolbox. The curve was fitted for an entire measured range of the sensor till an output of the sensor was in saturation between 5 to 6 N as observed by the reducing gradient with increasing applied force. The second order polynomial fit 1402 to the full range of the sensor, of up to 5 N, provides a value of R² error=0.9551 and a value of RMSE=27.9763. The polynomial model 1402 was built to better understand a physical phenomenon in effect as part of the sensing mechanism explained in FIGS. 11A and 11B.

The two models as shown in FIGS. 13 and 14 can be explained by the expected physical effects in relation to pressures applied by the user using the wearable glove. Particularly, part of the sensing response (i.e. measured capacitance change) is owed to an increase in a contact surface area of the human skin on the sensor as the pressure increases. At a certain threshold, this area will saturate as the skin cannot compress along the sensor anymore, leading to the saturation as shown in FIG. 14.

The linear range of the sensor as shown in FIG. 13 corresponds to a pressure range when a total contact surface area of the skin to the sensor plates (i.e. both the contacting member and the sensing member) continues to increase. This is because human skin is compliant and deformable. In other words, as the applied force of the input increases, the contact surface areas of the skin with the sensor plates also increase. This leads to the linear model as observed in FIG. 13. At higher forces, the measure capacitance of the sensor tends to “level off” or saturate as shown in the model of FIG. 14. This is likely because at a certain threshold, a rate of increase of the total contact surface area starts to reduce as most of the skin is now in contact with the sensor.

Nonetheless, for practical applications, this is hardly a concern as the sensor is expected to be used in a range of force of under 2 N. In addition, in cases where larger forces are to be measured, there would be larger corresponding interacting surface areas. This is because it is expected that a force output by a user will scale proportionally with a contact surface area. Otherwise, this would mean there exists a large pressure acting on a part of the human body which would inevitably damage the human body. In turn, this means a proportionately larger sensor would still be able to work in its linear range. Thus, the sensor of the present disclosure is expected to be scalable.

The two models as described in relation to FIGS. 13 and 14 therefore highlight a practical use case and its underlying physical phenomenon. It should be appreciated that in this case, the contact surface area was limited by the fact that the contacting surface for the sensor was the human finger. In other embodiments, the sensor can be used to sense pressures or forces in other applications. For example, the sensor of the present disclosure can be used to detect heel strike, as is common in gait analysis. In this case, a proportionately larger sensor may be used. This means that the sensor has a larger area of contact and a larger potential contacting surface (e.g. a heel) which will likely provide a larger saturation threshold.

FIG. 15 shows a graph of a loading curve 1502 and an unloading curve 1504 as measured by a wearable sensor in accordance with an embodiment.

Extending from the loading data shown in FIG. 14, FIG. 15 shows a hysteresis loop of the sensor on a typical cycle of loading and unloading. Based on the graph of FIG. 15, it is shown that the sensor output in the unloading cycle 1504 was slightly higher than for the same corresponding force on the loading cycle 1502. This can be explained by the fact that the contact surface area when reducing from a maximum load (graduate reduction of force) is larger than the contact surface area when increasing the load from zero. Thus, the hysteresis appears to stem from a differential contact surface area, which is inherent in the physical properties of wearable sensing, rather than being related to a property of the sensing electrodynamics of the wearable sensor.

### Summary of the Features of a Wearable Sensor of the Present Disclosure

In summary, a wearable sensor (e.g. a soft fabric sensor) that is capable of tactile sensing as well as pressure sensing was described. An exemplary manufacturing method for forming the wearable sensor using available e-textiles that requires no specialized equipment or materials was also described. The wearable sensor of the described embodiments uses a sensing mechanism involving a capacitance of a portion of the user (can be a partial or total portion) being in parallel with a capacitance of the wearable sensor. This provides a number of advantages. One of the advantages is that the sensor response with respect to its baseline is large, at about 800-1000%. This makes it easy and viable for the wearable sensor to be used in threshold-based detection. The measured sensor response of 800-1000% of the baseline is also much larger than most existing capacitive sensors, which possess a response of about 100-250% of the baseline. In fact, the response of the present wearable sensor was comparable to resistive sensors which in general tend to possess higher range of response than capacitive sensors. Such large magnitudes of output responses allow for reliable detection, as well as the ability to set conservative or low thresholds to minimize false detections.

Another advantage of the wearable sensor is in relation to its latency. For a good user experience in relation to human computer interaction (HCI), a latency of under 10 ms is generally expected. Most conventional input devices have a latency of between 1 ms to 4 ms. As described in relation to FIGS. 12A to 12C, the latency of the wearable sensor was measured using the load cell as the “ground truth”. The sensor was seen to respond about 75 ms faster than the load cell at a given sampling rate on the Teensy 4.0. This shows that the sensing mechanism is in fact very usable in wearables or input devices. In addition, the spread of the latency data observed was quite small, which means that the detection latency is quite consistent. It is expected that if a faster microcontroller is used for these experiments, the present performance metric of the wearable sensor can be improved due to faster processing speeds. Nonetheless, even in the present state, the sensor is faster than previously developed sensors that possess a latency between about 10 ms to 20 ms. It is also demonstrated that the sensor and its signal processing method was fast enough to distinguish signals at latency lower than 60 ms, which is much faster than what would be required in a conventional HCI application. For example, as shown in FIG. 11A, a one-second snapshot of the data included about 30 measured capacitance peaks (i.e. about 30 inputs received from the user). This reflects that the sensor was able to detect at a frequency of more than 30 Hz (i.e. fast enough to distinguish signals at latency of around 33 ms). It should be appreciated that this example is limited, however, by the frequency of the user input. As discussed in relation to FIG. 20, theoretical calculation shows that the sensor can distinguish signals at latency in the tens of nanoseconds range.

The sensor described is also capable of handling high frequency input that exceeds 30 Hz. This makes it ideal for Human Computer Interaction (HCI) and gaming. The sensor of the present disclosure thus presents a promising case for use in areas such as virtual reality (VR) gaming where a soft and wearable sensor is desired for comfort. At present, soft sensors are generally unusable due to high latency and hysteresis that is due to the conventional sensing mechanism being heavily reliant on mechanical deformations. This translates to mechanical hysteresis which induces electrical hysteresis in the response of these conventional sensors. For the wearable sensor of the present disclosure, the hysteresis observed was induced by the sensing method as described in relation to FIG. 15. Due to the nature of the hysteresis for the sensor of the present disclosure, it may be possible to use an edge detection algorithm to detect when the sensor is loading and/or unloading so that a corresponding output response curve of the sensor can be used in circumventing this effect of hysteresis. Circumventing this issue allows for greater diversity of use cases and practical applications.

When used in the wearable glove as demonstrated in the performed experiments, the sensor response was observed to be slightly dependent on the user. This is due to factors such as contact effects, contact resistances, capacitances of the user, and tightness of glove fit among others. Dynamic calibration can be used to overcome these problems in a relatively straightforward way by adjusting a baseline using a mean and variance of the sensor reading when initializing the sensor. In this case, the baseline of the sensor can be adjusted using the mean and variance based on a five-second sample of data in the worn state. This simple on-the-fly calibration also helps to quantify an approximate value of the noise, further increasing a robustness of the sensing scheme. It is noted that a need for recalibration of the sensor as described above in wearable applications is not unique to the sensor of the present disclosure, as most wearable sensors require this due to contact effects.

Further, the present sensor and sensing method provide a user dependent response. In other words, no other person or environmental triggers can activate the sensor, whether intentionally or accidentally apart from the user. This was explained in relation to FIGS. 2A and 2B, where it is discussed that another user will not be able to interfere with the loop being formed unless being in electrical contact with both the contacting member and the sensing member of the sensor. This ensures that false detections are greatly minimized, which is ideal for input devices. It also prevents accidental detections due to stray objects touching or interfering with the sensor. This feature is ideal for an application that involves the sensors being used to control other wearable devices worn by the user, such as an assistive exosuit or glove.

Table 2 below provides a summary of the characteristics of the wearable sensor of the present disclosure in the touch mode, while Table 3 below provides a summary of the characteristics of the wearable sensor of the present disclosure in the pressure mode.

### Touch Mode:

TABLE 2
Characteristics of the wearable sensor in touch mode

| Characteristic | Quantity (Units) | |
|---|---|---|
| Response time | ~0.1 | ms |
| Max detection frequency | >30 | Hz |
| Signal to Noise Ratio | ~22 | dB |

| | |
|---|---|
| Impulse sensitivity (Capacitance change | Up to 6000 pF / N |
| per unit force input for an impulse signal) | |

### Pressure Mode:

TABLE 3
Characteristics of the wearable sensor in pressure mode

| Characteristic | Quantity (Units) |
|---|---|
| Minimum detection load | <0.03 N or 3 g (see e.g. FIG. 9A) |
| Saturation Load | ~6 N or 600 gm |
| Linearity | ~95% |

The sensor of the present disclosure is ideal to be used in human-centered applications owing to its mechanism of sensing. Some applications include: human-computer interaction (HCI) interface, gaming interface using sensor array, control interface for wearable assistive devices/prosthesis, soft control mechanisms on devices such as headphones, soft pressure sensor for gait analysis, and wearable keyboard. Some of these applications are described below in relation to FIGS. 16 to 19B.

FIG. 16 shows an illustration of a gaming input device 1600 comprising a plurality of wearable sensors 100 of FIG. 1 in accordance with an embodiment.

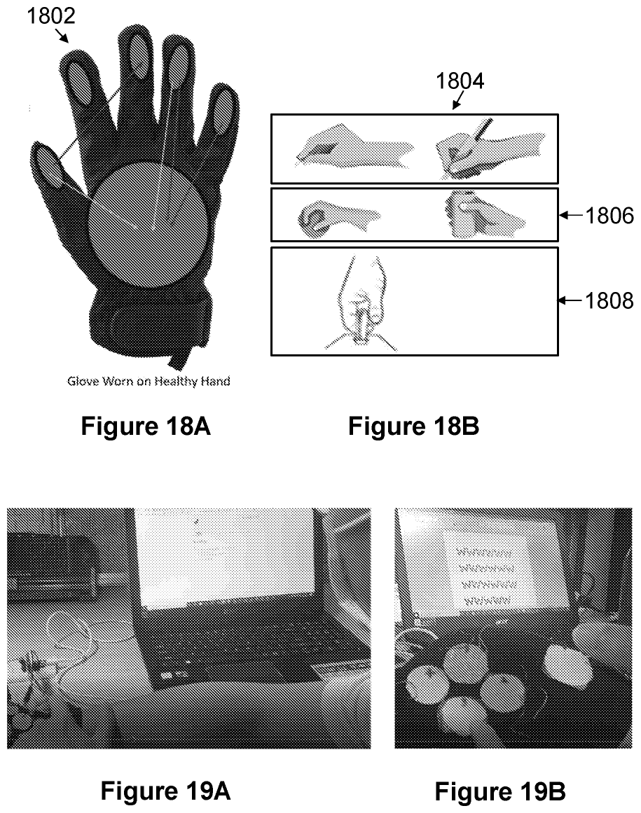

Given a low latency of the wearable sensor as described above, the wearable sensor of the present disclosure can be applied in gaming, particularly as a gaming input device 1600. Generally, gamers can reach up to 14 actions per second. Although these actions may relate to different input triggers, it still poses a challenge for an input device. As a result, gaming hardware has specific high-performance components and low latency mechanical switches. It was tested that use of the tactile sensing mode of the wearable sensor of the present disclosure for an arcade game exhibits imperceptible lag, comparable to a conventional gaming input device. As shown in FIG. 16, the gaming input device 1600 includes a D-pad control 1602 and sliding control bars 1604 on one glove, and other controls (which may be responsive to combinations of these sensor pads 1606, see e.g. in relation to FIG. 18) on another glove 1608. It is also demonstrated that the sensor of the present disclosure is able to resolve pressure as analog inputs as emulated by the D-pad control as a joystick. Analog input can be crucial to certain games, such as racing simulators where the adjustment of the pressure can be interpreted to a change in speed or sharpness in turning. In other words, a same wearable sensor can function in either a tactile sensing mode or a pressure sensing mode as used in the gaming input device 1600 of FIG. 16. That is, a same wearable sensor can also be used for both tactile sensing and pressure sensing. For example, touching of a button on the gaming input device 1600 may provide a signal that this button is triggered and a pressure applied to this same button can provide a magnitude of an input associated with the button (e.g. a rate of acceleration in a car racing game).

FIGS. 17A and 17B show illustrations to demonstrate use of the wearable sensor of FIG. 1 as an insole-based or sock-based gait analysis sensor in accordance with an embodiment.

FIG. 17A shows an illustration of placements of three wearable sensors in an insole or a sock. In either case, for use as a pressure sensor (i.e. in the pressure measuring mode), the contacting member of the wearable sensor is always in electrical contact with a first part of a foot of the person and the sensing member of the wearable sensor is also in constant electrical contact with a second part of the foot (e.g. provided by use of conductive thread). As the user steps, pressures applied on the sensors change with the motion of the user, and based on the pressure-force relationship graphs (e.g. as described in relation to FIGS. 13 to 15), the portion of the foot which is in contact with the ground can be determined. This can be used to determine different phases of a gait cycle as described in relation to FIG. 17B below. In this application, the high gauge factor of the wearable sensor is being utilized.

FIG. 17B shows an illustration of different phases of a gait cycle. As illustrated in Table 4 below, different phases of the gait cycle can be deduced based on outputs of the wearable sensors at the three different locations of the sole or sock.

TABLE 4
Example of an application of the wearable sensor
as a pressure sensor in gait analysis

| Gait Phase | Sensor 1 (S1) | Sensor 2 (S2) | Sensor 3 (S3) |
|---|---|---|---|
| Heel Strike 1710 | High | Low | Low |
| Footflat 1712 | Medium | Medium | Medium |
| Midstance 1714 | Reducing | Medium | Medium |
| Push off 1716 | Low | Low | High |

FIGS. 18A and 18B show illustrations of the wearable sensor of FIG. 1 being applied in a wearable control glove for a hemiparetic patient in accordance with an embodiment.

FIG. 18A shows an illustration of the wearable control glove 1802 to be worn on a healthy hand of the hemiparetic patient. This may be similar to the glove 1608 for a gaming input device as described in relation to FIG. 16. The wearable control glove 1802 is able to provide combinations of different inputs as illustrated in FIG. 18A. FIG. 18B shows an illustration of controls provided on the assisted hand in relation to a combination of inputs provided by the wearable control glove 1802. The different combinations can provide a pinch grasp 1804, a spherical grasp 1806 or a hook grasp 1808 as illustrated in FIG. 18B. Exemplary input combinations are listed in Table 5 below.

TABLE 5
Examples for control of an assisted hand

| Combination (Glove) | Control (Assisted Hand) |
|---|---|
| Thumb + Finger | Pinch Grasp with given finger(s) |
| Thumb + Finger + Palm | Spherical Grasp |
| Fingers + Palm (i.e. without Thumb) | Hook Grasp |

FIGS. 19A and 19B show illustrations of the wearable sensor of FIG. 1 being applied in an input device to a computer or laptop in accordance with an embodiment.

FIG. 19A shows an illustration of the input device as a gaming input or numeric pad interface, and FIG. 19B shows an illustration of the input device as a keyboard.

Keyboards are important human computer interfaces as they allow for multiple types of interaction, such as typing documents, writing codes as well as gaming. Low latency is desired in keyboard applications as it is possible to reach up to 1000 characters per minute. This means that any perceptible lag in the sensing will render the sensor unusable to the user. Thus, this is an application in which the low input latency of the wearable sensor of the present embodiment has an inherent advantage. FIG. 19A shows the use of the gaming input device for playing a built-in game (e.g. the dinosaur jumping over the cactus) on Chrome™ to showcase the low latency of the sensors in the gaming input device (e.g. a high latency will render the game unplayable). As shown in FIG. 19B, the wearable sensors of the present disclosure have been used as keyboard inputs and it was observed that the latency was imperceptible. It is envisaged that the wearable sensors can be applied to a full-scale wearable keyboard for typing, or for replicating/playing musical instruments that can be worn on a user.

FIGS. 20 to 24 relate to further materials for explaining the HIL circuit of FIGS. 2A and 2B, as well as some of the experimental results as discussed in relation to FIGS. 10A to 12C.

FIG. 20 shows a diagram of an extended circuit 2000 of the equivalent circuit 212 of FIG. 2A in accordance with an embodiment. The extended circuit 2000 comprises a user capacitance 2002 in parallel with a sensor capacitance 2004 when the sensing member is in electrical contact with the second part of the user, a microcontroller 2006 for measuring a timing constant of the circuit 2000, and resistances 2008, 2010. The timing constant of the circuit 2000 measured using the microcontroller 2006 can be used to detect and/or infer a change in capacitance in response to a tactile input and/or a pressure input received by the wearable sensor from the user. From FIG. 20, a sensing system comprising a wearable sensor and an integrated circuit for detecting a change in capacitance in response to the electrically conductive sensing member detecting the input via the electrical contact caused by the second part of the user can therefore be envisaged. The resistance of the conductive thread is quite small (2Ω) and is this neglected. R_{Human} is the resistance of the human and is expected to be divided approximately in half around each of the conducting member and the sensing member of the sensor. The fabric resistance R_{fabric} and the sensor capacitance Cₛₑₙₛₒᵣ 2004 are in parallel with R_{Human} and the human capacitance C_{Human} 2002. When the user makes contact 2012 with the sensing member of the sensor, the circuit 2000 is completed as shown by a dotted line in FIG. 20. The completion of the circuit 2000 leads to an increase in a net capacitance, owing to the fact that the C_{Human} 2002 is now added in parallel to the sensor capacitance Cₛₑₙₛₒᵣ 2004. In addition, there are some effects that also affect the resistive properties of the circuit 2000. The materials used for the sensing plates, i.e. conductive fabrics which are used to form the contacting member and the sensing member, tend to be piezoresistive. The resistance of these fabrics drops when pressure is applied to them. In addition, a contact resistance (not shown) can also added into the circuit. The contact resistance is due to the contact of the human skin with the conductive plates on both sides. As the pressure increases, the contact resistance also changes. However, it is quite difficult to model, as factors such as sliding, and skin conductivity also play a role in determining it.

FIGS. 21 and 22 are included to provide further discussion in relation to the obtained for FIGS. 10A and 10B, and FIGS. 11A and 11B.

FIG. 21 shows a plot 2100 of capacitance measured using the wearable sensor of FIG. 4C to illustrate examples of rejected peaks which are removed for high frequency analysis of the wearable sensor in accordance with an embodiment. In analysing the measured data for high frequency input experiments performed in relation to FIGS. 10A, 10B, 11A and 11B, the MATLAB function findpeaks was used to detect peaks. This function allows inputs for: (i) a threshold to be defined, below which the peaks are ignored, (ii) a sampling rate to be defined, for converting the sample number of the data into a timeline and (iii) a proximity filter to be used for rejecting peaks in close proximity that are likely due to noise.

The peak detection algorithm filters the peaks based on certain criteria. First, any peaks under the set threshold are ignored. This was set as 0.06 N for the load cell and 65 pF for the wearable sensor. Second, peaks in near proximity are ignored. This proximity for 250 samples with a sampling rate of 20 kHz comes down to 12.5 ms. This is faster than what the sensor is expected to perform for its applications, and rejecting peaks within this 12.5 ms band makes the system even more robust against false or noisy detections. An example of the peaks 2102 that would be rejected due to this proximity filter is shown in FIG. 21.

FIG. 22 shows plots 2200 of normalised values of the wearable sensor of FIG. 4C and normalised values of the load cell for illustrating missed peaks of the load cell in accordance with an embodiment.

As shown in FIG. 22, the labels of the algorithm detected peaks for the sensor and the load cell were marked with ‘c’ and ‘I’ respectively. It is noted that in this cropped sample, the sensor peak c7 2202 was not detected by the load cell with a corresponding peak. The reason for this may be that the force was too small for detection by the load cell, or that the impulse was too short. Both of these factors could lead to a missed detection by the load cell. Another likely scenario may be that the mechanical effect of the deformation of the strain gauge caused delay for the load cell to return back to its original position, thereby resulting in the missed detection. This is similar to what is seen around c10 2204 where the two sensor peaks showed up as one load cell peak.

The load cell used in the experiments was observed to possess hysteresis that prevents it from distinguishing between impulses that are temporally too close to one another. Further, the response peaks of the load cell were also flatter as compared to the sharper peaks measured using the sensor. As a result, latency calculations were thrown off by this data set, and a separate set of data was collected for calculation of latency of the sensor. This is shown and discussed in relation to FIGS. 23 and 24 below.

### Latency Test

The limit for the latency is a function of the capacitance being measured and the resistance in the circuit. Reference can be made to the extended circuit 2000 as shown in FIG. 20. The sensor can be scaled up or down based on requirements. The following calculation can serve as a guide for the expected sensing latency:

$$τ = RC$$

where t is the timing constant of the circuit, R is the series resistance and C is the capacitance being measured.

R is variable due to the in-loop effects as described in the physical model, and C is variable due to an interaction of the user.

The sensing latency is at least as much as the timing constant (12 pF going to 400 pF), as the charging cycle must be completed in order to get a reading from the capacitive sensor. In case of a small sensor such as that aforementioned described with a resistance of 200Ω in series, this timing constant can be calculated as:

$$T = 200 \times 400 \times {10}^{- 12} = 80 ns$$

This is much faster than a sampling rate of most available devices. Thus, the sampling rate is the actual limiting factor. The limit in the sampling rate may be due to the sampling rate of the microcontroller and/or the ADC convertor used in the present embodiment.

The sensing latency can therefore be considered as the minimum of the expected maximum timing constant and the inverse of the sampling rate.

$$Latency = min ( max ( τ ) , 1 / sampling rate )$$

FIG. 23 shows plots 2300 of normalised values of the measured capacitances of the wearable sensor of FIG. 12A to illustrate activation peaks detection by applying a normalised sensor threshold value of 0.2 in accordance with an embodiment. FIG. 24 shows plots 2400 of normalised values of the measured resistances of the load cell of FIG. 12A to illustrate activation peaks detection of the load cell by applying a normalised load cell threshold value of 0.2 in accordance with an embodiment. FIGS. 23 and 24 also show the raw data for the sensor and the load cell, respectively, of the 2 Hz input rate data set.

Similar to FIGS. 21 and 22, the MATLAB findpeaks function for the detection of the sensor peaks was used to detect peaks for the plots 2300 and 2400. The sensor peaks are represented by s1 to s20 whereas the load cell peaks are represented I1 to I20. The data 2302 and 2402 of the sensor and the load cell, respectively, is the data used for peak detection. The sensor data 2302 is noisy and so a threshold filter was applied to the sensor data (i.e. “thresholded”) before being passed through the peak detection algorithm. This was done since in practice, a threshold-based detection would also be used. Thus, the peak detection using the “thresholded” data accurately represents what was expected to occur in a real-world application. The data 2304 is the raw sensor signal 2304, normalized with respect to the maximum value. The horizontal lines 2306, 2404 represent the threshold values of 0.2 set for the sensor and the load cell, respectively.

It can be seen from FIGS. 23 and 24 that the load cell peaks are much sharper due to the low frequency of the tactile input. This is due to the fact that the load cell reading can stabilize in this low frequency unlike in the high frequency input as shown earlier in relation to FIGS. 21 and 22.

The low response time of the sensor and its ability to detect rapid taps makes the sensor ideal in applications such as real-time control, human-computer interaction, and gaming. The low form factor and low mechanical impedance makes these sensors ideal for wearable devices. The sensor also possesses a very high signal to noise ratio, high sensitivity and low hysteresis making it reliable. The sensor can double up as a tactile sensor for low latency input or as an analog pressure sensor making it highly versatile, opening an array of applications.

Other embodiments include: (1) the electrically conductive contacting member and/or the electrically conductive sensing member being made of a conductive material or a flexible conductive material (e.g. a conductive material which enables good contact between a skin of the user and the contacting member or the sensing member, such as graphene or a graphite-based material) other than a conductive fabric; (2) contacting the sensing member of the wearable sensor electrically by means of a non-direct physical contact (e.g. via an electric conductor); (3) the first part and/or the second part of the user includes any body part of the user viable for fitting a wearable sensor; (4) the user may be a human or an animal; (5) using other forms of methods to form the conducting member and the sensing member of the wearable sensor other than Silhouette Cameo®; (6) the dielectric used in the wearable sensor comprises one or more of: a 3D printed dielectric, a moldable elastomer, a silicone, a compressible dielectric, an insulating material, an insulating foam and an insulating fabric; (7) providing two or more sensors (e.g. including more than 3 sensors) in the sole or the sock for gait analysis; (8) use of other circuits or components (e.g. a multimeter) besides the microcontroller and/or the timing constant of the circuit as described to detect a change in capacitance of the sensor; (9) protecting the sensing member and/or the contacting member using protective films or layers (e.g. other forms of thin, flexible plastic layers) other than tapes as previously described; (10) wearable sensors which do not comprise protective layers, e.g. if the materials used for the sensing member and/or the contacting member are not prone to fraying; and (11) shapes and/or sizes of the wearable sensor which vary with an application of the wearable sensor.

Although only certain embodiments of the present invention have been described in detail, many variations are possible in accordance with the appended claims. For example, features described in relation to one embodiment may be incorporated into one or more other embodiments and vice versa.

1. A wearable sensor comprising:
an electrically conductive contacting member adapted to be in constant electrical contact with a first part of a user of the wearable sensor;
an electrically conductive sensing member adapted to detect an input via an electrical contact caused by a second part of the user; and
a dielectric sandwiched between the contacting member and the sensing member to provide a sensor capacitance,
wherein, in use, the constant electrical contact and the electrical contact caused by the second part of the user form a capacitive circuit comprising a capacitance of a portion of the user in parallel to the sensor capacitance.

2. The wearable sensor of claim 1, wherein the input comprises a direct physical contact between the sensing member and the second part of the user.

3. The wearable sensor of claim 1, wherein the sensing member is adapted to be in constant electrical contact with the second part of the user and wherein the dielectric is compressible or at least one of the contacting member and the sensing member is piezoresistive, the input comprises a force exerted by the second part of the user on the sensing member.

4. The wearable sensor of claim 1, wherein the second part of the user includes one or more fingers of the user.

5. The wearable sensor of claim 1, wherein the contacting member and the sensing member are each made of a conductive fabric.

6. The wearable sensor of claim 5, further comprising a first protective layer attached to the contacting member and a second protective layer attached to the sensing member for strengthening edges of the conductive fabric of each of the contacting member and the sensing member to prevent fraying.

7. The wearable sensor of claim 1, wherein the dielectric comprises one or more of: a 3D printed dielectric, a moldable elastomer, a silicone, a compressible dielectric, an insulating foam and an insulating fabric.

8. A wearable input device comprising a plurality of input pads, wherein each of the plurality of input pads comprises a wearable sensor of claim 1.

9. The wearable input device of claim 8, configured to receive a device input provided by having two or more sensing members of the plurality of input pads in electrical contact with one another.

10. The wearable input device of claim 8, comprising one of: a wearable keyboard and a wearable glove.

11. A pressure sensing device for gait analysis, the pressure sensing device comprising two or more wearable sensors of claim 3, wherein the contacting member of each of the two or more wearable sensors is adapted to be in constant electrical contact with a first part of a foot of the user and the sensing member of each of the two or more wearable sensors is adapted to be in constant electrical contact with a second part of the foot.

12. The pressure sensing device of claim 11, wherein the two or more wearable sensors include a first wearable sensor located at a heel area of the foot, a second wearable sensor located at a mid-foot area of the foot and a third wearable sensor located at a toe area of the foot.

13. The pressure sensing device for claim 11, wherein the contacting member and the sensing member are made of piezoresistive conductive fabric.

14. A sensing system comprising:
the wearable sensor of claim 1; and
an integrated circuit for detecting a change in capacitance in response to the electrically conductive sensing member detecting the input via the electrical contact caused by the second part of the user.

15. A sensing method using a wearable sensor, the wearable sensor comprising an electrically conductive contacting member, an electrically conductive sensing member and a dielectric sandwiched between the contacting member and the sensing member to provide a sensor capacitance, the method comprising:
placing the contacting member in constant electrical contact with a first part of a user; and
detecting an input by the sensing member via an electrical contact caused by a second part of the user,
wherein the constant electrical contact and the electrical contact caused by the second part of the user form a capacitive circuit comprising a capacitance of a portion of the user in parallel to the sensor capacitance.

16. The sensing method of claim 15, wherein detecting the input comprises detecting a direct physical contact between the sensing member and the second part of the user.

17. (canceled)

18. (canceled)

19. A method for forming a wearable sensor, the method comprising:
(i) forming an electrically conductive contacting member of the wearable sensor, the contacting member being adapted to be in constant electrical contact with a first part of a user of the wearable sensor;
(ii) forming an electrically conductive sensing member of the wearable sensor, the sensing member being adapted to receive an input via an electrical contact caused by a second part of the user; and
(iii) forming a dielectric between the contacting member and the sensing member,
wherein the contacting member and the sensing member are made of conductive fabric.

20. The method of claim 19, wherein each of the steps (i) and (ii) comprises:
attaching a protective layer on a surface of the conductive fabric to form a conductive fabric assembly to prevent fraying of edges of the conductive fabric; and
shaping the conductive fabric assembly.

21. The method of claim 19, wherein the step (iii) comprises forming the dielectric using additive manufacturing, the method further comprises:
obtaining an electronic file representing a geometry of the dielectric; and
controlling an additive manufacturing apparatus to manufacture, over one or more additive manufacturing steps, the dielectric according to the geometry specified in the electronic file.

22. The method of claim 19, wherein the dielectric includes a moldable elastomer, the step (iii) comprises:
forming a mold;
providing the moldable elastomer in the mold; and
curing the moldable elastomer.
